(19) United States
(12) Patent Application Publication
(10) Pub. No.: US 2026/0215246 A1
(43) Pub. Date: Jul. 23, 2026

(54) SEMICONDUCTOR MEMORY DEVICE

(71) Applicant: Samsung Electronics Co., Ltd., Suwon-si (KR)

(72) Inventors: Nayeong YUN, Suwon-si (KR); Sang-Yong PARK, Suwon-si (KR); Kibong MOON, Suwon-si (KR); Seung Jae BAIK, Suwon-si (KR); Sung-Bok LEE, Suwon-si (KR); Jaeduk LEE, Suwon-si (KR)

(73) Assignee: Samsung Electronics Co., Ltd., Suwon-si (KR)

(21) Appl. No.: 19/419,390

(22) Filed: Dec. 15, 2025

(30) Foreign Application Priority Data
Jan. 17, 2025 (KR) 10-2025-0007477

(51) Int. Cl. H10W 20/42; G11C 16/04; H10B 43/10; H10B 43/27; H10B 43/35; H10D 80/30; H10W 20/41; H10W 20/43

(52) U.S. Cl. CPC H10W 20/422; G11C 16/0483; H10B 43/10; H10B 43/27; H10B 43/35; H10D 80/30; H10W 20/43; H10W 20/435

(57) ABSTRACT

Provided is a semiconductor memory device including a cell substrate including a channel region and a stair region, a hole cut structures that are placed on a front side of the cell substrate, a memory cell block, and a connection structure, and the memory cell block includes a mold structure including gate electrodes that are spaced apart from each other, and are stacked in a stair shape in the stair region, a channel structure that penetrates the mold structure in the channel region and a stair region via that is connected with the gate electrodes stacked in the stair shape in the stair region, the hole cut structures includes a hole cut conductive layer and a hole cut insulating layer configured to cover the hole cut conductive layer, and the connection structure is configured to connect the stair region via and the hole cut conductive layer.

### CROSS-REFERENCE TO RELATED APPLICATIONS

This application claims priority under 35 USC § 119 to the benefit of Korean Patent Application No. 10-2025-0007477, filed on Jan. 17, 2025, in the Korean Intellectual Property Office, the disclosure of which is incorporated herein by reference in its entirety.

### BACKGROUND

Some example embodiments relate to a semiconductor memory device.

With the rapid development of the electronics industry and the demands or expectations of users, electronic devices are becoming smaller, with more capacity, and more functionality. To implement these functions, the integration density of semiconductor memory devices is being increased.

To increase the integration density of semiconductor memory devices, memory cell sizes are shrinking, and the interconnection structures for the operation and electrical connection of semiconductor memory devices are also becoming more complex.

### SUMMARY

Some example embodiments may provide a semiconductor memory device and/or a method of manufacturing the semiconductor memory device by which performance is improved with simplifying an interconnection structure and reducing or minimizing parasitic resistance. Alternatively or additionally, some example embodiments provide a semiconductor memory device and/or a method of manufacturing the semiconductor memory device wherein integration density is improved with minimizing or the space required due to the interconnection structure.

The technical tasks to be achieved by some example embodiments are not limited to the technical tasks described above, and other technical tasks may be inferred from the following example embodiments by those of ordinary skill in the art.

According to some example embodiments, there is provided a semiconductor memory device including a cell substrate including a channel region and a stair region, a plurality of hole cut structures on a front side of the cell substrate and spaced apart from each other, a memory cell block between the plurality of hole cut structures spaced apart from each other, and a connection structure including a conductive material. The memory cell block includes a mold structure including gate electrodes spaced apart from each other in a first direction in the channel region and the stair region of a front side of the cell substrate, and stacked in a stair shape in the stair region, a channel structure penetrating at least a portion of the mold structure in the channel region in the first direction, and a stair region via connected with the gate electrodes stacked in the stair shape in the stair region and extending in the first direction. Each of the plurality of hole cut structures includes a hole cut conductive layer and a hole cut insulating layer covering at least a portion of the hole cut conductive layer and extending in a second direction intersecting the first direction, and the connection structure connects the stair region via and the hole cut conductive layer.

Alternatively or additionally according to some example embodiments, there is provided a semiconductor memory device including a cell region and a peripheral circuit region in the cell region. The cell region includes a cell substrate including a channel region and a stair region, a plurality of hole cut structures on a front side of the cell substrate and spaced apart from each other, a memory cell block between the plurality of hole cut structures that are spaced apart from each other, and a hole cut back side contact including a conductive material. The peripheral circuit region includes a peripheral circuit insulating layer on a back side of the cell substrate and a peripheral circuit interconnection structure in the peripheral circuit insulating layer. The memory cell block includes a mold structure including gate electrodes spaced apart from each other in a first direction in the channel region and the stair region of a front side of the cell substrate, and stacked in a stair shape in the stair region, and a channel structure penetrating at least a portion of the mold structure in the channel region in the first direction. Each of the plurality of hole cut structures that are spaced apart from each other includes a hole cut conductive layer and a hole cut insulating layer covering at least a portion of the hole cut conductive layer and extending in a second direction intersecting the first direction, and the hole cut back side contact connects the peripheral circuit interconnection structure and the hole cut conductive layer.

Alternatively or additionally according to some example embodiments, there is provided a semiconductor memory device including a cell region and a peripheral circuit region placed in the cell region. The cell region includes a cell substrate including a channel region and a stair region, a plurality of hole cut structures on a front side of the cell substrate and spaced apart from each other, a memory cell block between the plurality of hole cut structures that are spaced apart from each other, a connection structure including a conductive material, and a hole cut back side contact including a conductive material. The peripheral circuit region includes a peripheral circuit insulating layer on a back side of the cell substrate, and a peripheral circuit interconnection structure in the peripheral circuit insulating layer. The memory cell block includes a mold structure including gate electrodes spaced apart from each other in a first direction in the channel region and the stair region of a front side of the cell substrate, and are stacked in a stair shape in the stair region, a channel structure penetrating at least a portion of the mold structure in the channel region in the first direction, and a stair region via connected with the gate electrodes stacked in the stair shape in the stair region and extending in the first direction. The hole cut structure includes a first hole cut structure including the hole cut conductive layer and a first hole cut insulating layer covering at least a portion of the hole cut conductive layer, and a second hole cut structure adjacent to the first hole cut structure and including a second hole cut insulating layer. The connection structure connects the stair region via and the hole cut conductive layer. The hole cut back side contact connects the peripheral circuit interconnection structure and the hole cut conductive layer, and a volume of the first hole cut structure is greater than a volume of the second hole cut structure.

Alternatively or additionally, there is provided a method of manufacturing a semiconductor memory device, the method including forming a stacked structure on a cell substrate, the stacked structure including a structure in which mold insulating layers and replacement insulating layers are alternately stacked in a first direction, the substrate including a first region, a second region and a third region, forming a first hole penetrating the stacked structure in the first region in a first direction, forming a second hole penetrating the stacked structure in the second region in the first direction, the second hole having greater volume than the volume of the first hole, forming a third hole penetrating the stacked structure in the third region in the first direction, forming a channel structure at the first hole, removing a replacement insulating layer and forming a gate electrode at a position where the replacement insulating layer is removed, forming a first hole cut insulating layer at a portion of the second hole, filling a second hole cut insulating layer in the third hole, forming a hole cut conductive layer on the first hole cut insulating layer to fill the second hole, forming a bit line connected with the channel structure and a connection structure connected with the hole cut conductive layer, and after flipping, forming a source back side contact penetrating the cell substrate in the first direction and connected with the channel structure and a hole cut back side contact penetrating the cell substrate in the first direction and is connected with the hole cut conductive layer.

In some example embodiments, the method of manufacturing the semiconductor memory device may include forming the first hole, the second hole and the third hole at a same time.

In some example embodiments, the method of manufacturing the semiconductor memory device may further include connecting a cell structure with a peripheral circuit structure including a peripheral circuit interconnection structure that is connected with the source back side contact and the hole cut back side contact.

In some example embodiments, the method of manufacturing the semiconductor memory device may further include forming a stair structure at a portion of the stacked structure before removing the replacement insulating layer.

In some example embodiments, the method of manufacturing the semiconductor memory device may further include forming a stair region hole in order for a gate electrode placed in the stair structure to be exposed after the gate electrode is formed, and forming a stair region via by filling the conductive material in the stair region hole.

In some example embodiments, the method of manufacturing the semiconductor memory device may further include connecting the stair region via and the hole cut conductive layer with the connection structure.

Specific details of the above and other example embodiments are included in the detailed description and drawings.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a block diagram of a semiconductor memory device according to some example embodiments;

FIG. 2 is a circuit diagram illustrating a semiconductor memory device according to some example embodiments;

FIG. 3 is a plan view illustrating a semiconductor memory device according to some example embodiments;

FIG. 4 is a plan view illustrating a semiconductor memory device according to some example embodiments;

FIG. 5 is a plan view illustrating a semiconductor memory device according to some example embodiments;

FIG. 6 is a plan view illustrating a semiconductor memory device according to some example embodiments;

FIG. 7 is a cross-sectional view taken along line A-A′ of FIG. 3;

FIG. 8 is an enlarged view of a portion P of FIG. 7;

FIG. 9 is a cross-sectional view taken along line B-B′ of FIG. 3;

FIG. 10 is a cross-sectional view taken along line C-C′ of FIG. 4;

FIG. 11 is a cross-sectional view taken along line A-A′ of FIG. 3;

FIG. 12 is a cross-sectional view taken along line B-B′ of FIG. 3; and

FIG. 13 to FIG. 33 are drawings for explaining a method of manufacturing a semiconductor memory device according to some example embodiments.

### DETAILED DESCRIPTION

The properties described may be measured in a room temperature and/or a room pressure environment unless specifically limited. As used herein, the room temperature is the natural temperature without any artificial manipulation, and may be 10° C. to 30° C., 20° C. to 28° C. or 22° C. to 26° C. In some example embodiments, the room temperature may be 25° C. In some example embodiments, the normal pressure is the natural pressure that has not been artificially manipulated, and the normal pressure can be 700 mmHg to 800 mmHg or 720 mmHg to 780 mmHg. In some example embodiments, the normal pressure may be 760 mmHg.

In some example embodiments, the properties mentioned may have units according to the international system of units unless otherwise specified.

Hereinafter, some example embodiments according to the technical idea of the inventive concepts will be described with reference to the attached drawings. Additionally, for brevity, existing elements, structures and/or layers of a semiconductor memory device according to an example may be or may not be described in detail herein. For example, when the separate structures or other structures included in the semiconductor memory device and/or the materials forming them are not related to the novel features of example embodiments, description thereon may be omitted.

The drawings illustrated herein are according to mere example embodiments, and the ratio of the width, the length and the height (or the thickness) of each element is for detailed descriptions for example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the − direction; example embodiments are not limited thereto.

As used herein, an insulating material may have an electric conductivity of less than 10⁻⁶ S/m. As used herein, the electric conductivity is not specifically limited, but may be measured as, for example, ASTM E 1004. For example, the insulating material may include at least one selected from the group consisting of or including silicon oxide, silicon-germanium oxide, germanium oxide, silicon oxynitride, germanium oxynitride, silicon nitride, germanium nitride, a high-k material having a dielectric constant higher than that of silicon oxide, and a low-k material having a dielectric constant lower than that of silicon oxide.

The high-k material may include one or more from the group consisting of or including, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. However, the high-k material is not limited thereto. The low-k material may include one or more from the group consisting of or including, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels and mesoporous silica. However, the low-k material is not limited thereto.

As used herein, the conductive material may have an electric conductivity of greater than 10⁶ S/m. For example, the conductive material may include at least one of a metal, a metal alloy, a conductive metal nitride, a metal silicide, a doped semiconductor material, a conductive metal oxide, and a conductive metal oxynitride. For example, the conductive material may include at least one selected from the group consisting of or including titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn) and vanadium (V). However, the conductive material is not limited thereto. The conductive metal oxide and/or conductive metal oxynitride may include oxidized forms of the above-described substances, but are not limited thereto.

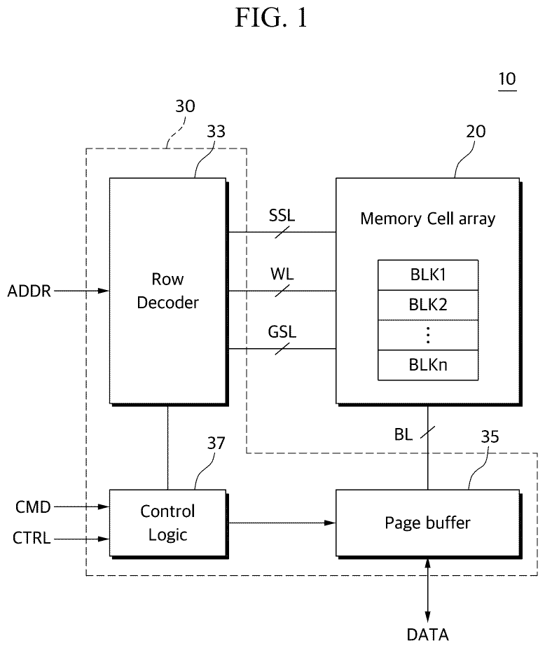

FIG. 1 is a block diagram of a semiconductor memory device 10 according to some example embodiments. The semiconductor memory device 10 may include a memory cell array 20 and a peripheral circuit 30.

In some example embodiments, the semiconductor memory device 10 may be, for example, a non-volatile memory device. In some example embodiments, the non-volatile memory device may be or may include, for example, one or more of flash memory, ROM, a hard disk, a diskette drive, magnetic tape, or an optical disk, but is not limited thereto. In some example embodiments, the non-volatile memory device may be flash memory. In some example embodiments, the flash memory may be NAND flash memory, and specifically, vertical NAND flash memory. In some example embodiments, the semiconductor memory device 10 may be, but is not limited to, a vertical NAND flash memory device.

In some example embodiments, the memory cell array 20 may include a plurality of memory cell blocks (BLK1 to BLKn). Each of the plurality of memory cell blocks (BLK1~BLKn) may include a plurality of memory cells. The memory cell array 20 may be connected to the peripheral circuit 30 through a bit line BL, a word line WL, a string select line SSL and a ground select line GSL.

In some example embodiments, the plurality of memory cell blocks (BLK1 to BLKn) may be connected to a row decoder 33 through the word line WL, the string select line SSL and the ground select line GSL. The plurality of memory cell blocks (BLK1~BLKn) may be connected to a page buffer 35 through the bit line BL. The plurality of memory cell blocks (BLK1~BLKn) may include dummy and/or redundant memory cell blocks; example embodiments are not limited thereto.

In some example embodiments, the peripheral circuit 30 may receive an address ADDR, a command CMD, and a control signal CTRL from the outside of the semiconductor memory device 10. The peripheral circuit 30 may transmit and/or may receive data DATA with a device external to the semiconductor memory device 10. The peripheral circuit 30 may include a control logic 37, the row decoder 33, and the page buffer 35. The peripheral circuit 30 may include various sub-circuits such as one or more of input/output circuit, voltage generation circuit for generating various voltages required for or used for operation of the semiconductor memory device 10, and error correction circuit for correcting errors in the data DATA read from the memory cell array 20 as needed.

In some example embodiments, the control logic 37 may be connected to the row decoder 33, input/output circuits, and voltage generation circuits. The control logic 37 may control at least some of or the overall operation of the semiconductor memory device 10. The control logic 37 may generate various internal control signals used within the semiconductor memory device 10 in response to the control signal CTRL. For example, the control logic 37 may adjust the level of voltage provided to the word line WL and/or the bit line BL when performing memory operations such as a program operation and/or an erase operation.

In some example embodiments, the row decoder 33 may select at least one of a plurality of memory cell blocks (BLK1 to BLKn) in response to the address ADDR, and select at least one word line WL, at least one string select line SSL, and at least one ground select line GSL of a selected memory cell block among a plurality of memory cell blocks (BLK1 to BLKn). The row decoder 33 may apply voltage to the word line WL of a selected memory cell block to perform a memory operation.

In some example embodiments, the page buffer 35 may be connected to the memory cell array 20 via the bit line BL. The page buffer 35 may act as a writer driver and/or as sense amplifier. When performing program operations, the page buffer 35 may act as a writer driver, and may apply a voltage to the bit line BL according to the data DATA to be stored in the memory cell array 20. When performing a read operation, the page buffer 35 may act as a sense amplifier, and may detect the data DATA stored in the memory cell array 20.

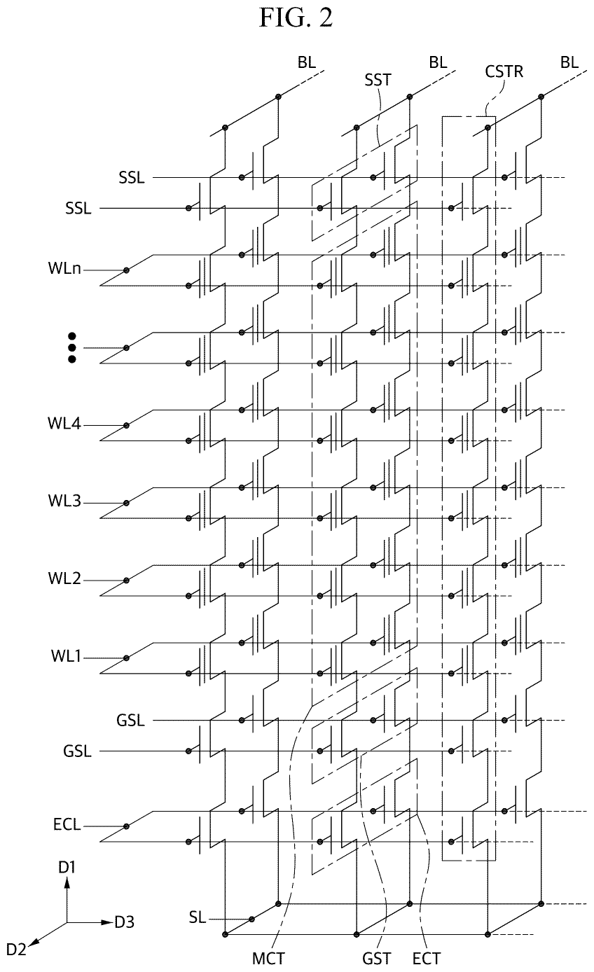

FIG. 2 is a circuit diagram illustrating a semiconductor memory device according to some example embodiments.

In some example embodiments, the memory cell array 20 of FIG. 1 of the semiconductor memory device 10 may include a source line SL, the bit line BL and a cell string CSTR.

In some example embodiments, referring to FIG. 2, the source line SL may be extended, for example, in the second direction D2. The memory cell array 20 of FIG. 1 may include a plurality of source lines SL, and the plurality of source lines SL may be arranged two-dimensionally. For example, the plurality of source lines SL may be spaced apart from each other and each may extend in the second direction D2. Each of the plurality of source lines SL may be supplied with an electrically identical voltage and in some example embodiments may be controlled concurrently, or the plurality of source lines SL may be supplied with different voltages so that the plurality of source lines SL may be controlled separately.

In some example embodiments, referring to FIG. 2, the bit line BL may extend in the third direction D3, intersecting the second direction D2. The memory cell array 20 of FIG. 1 may include a plurality of bit lines BL, and the plurality of bit lines BL may be arranged two-dimensionally. For example, the plurality of bit lines BL may be spaced apart from each other and each may extend in the third direction D3. The cell string CSTR may be connected to each of the plurality of bit lines BL.

In some example embodiments, the memory cell array 20 of FIG. 1 may include a plurality of cell strings CSTR. Each of the plurality of cell strings CSTR may be connected in parallel to each of a plurality of bit lines BL. The plurality of cell strings CSTR may be connected to the source line SL. The plurality of cell strings CSTR may be placed between the bit line BL and the source line SL.

In some example embodiments, each of the plurality of cell strings CSTR may include a ground select transistor GST connected to the source line SL, a string select transistor SST connected to the bit line BL, and a memory cell transistor MCT arranged between the ground select transistor GST and the string select transistor SST. A plurality of memory cell transistors MCT may be arranged. Each of the plurality of memory cell transistors MCT may include a data storage element. The ground select transistor GST, the string select transistor SST and the memory cell transistor MCT may be connected in series.

In some example embodiments, the source line SL may be connected to the source of the ground select transistor GST. Between the source line SL and the bit line BL, the ground select line GSL, a plurality of word lines (WL1, WL2, WL3, WL4, . . . , WLn) and the string select line SSL may be placed. The ground select line GSL may be used as the gate electrode of the ground select transistor GST. The plurality of word lines (WL1, WL2, WL3, WL4, . . . , WLn) may be used as the gate electrode of each of the plurality of memory cell transistors MCT. The string select line SSL may be used as the gate electrode of the string select transistor SST. The number of the plurality of word lines (WL1, WL2, WL3, WL4, . . . , WLn) may be the same as, or different from (e.g., greater than or less than) the number of blocks (BLK1, . . . BLKn).

In some example embodiments, an erase control transistor ECT may be placed between the source line SL and the ground select transistor GST. The source line SL may be connected to the source of the erase control transistor ECT. An erase control line ECL may be placed between the source line SL and the ground select line GSL. The erase control line ECL may be used as the gate electrode of the erase control transistor ECT. The erase control transistor ECT may perform an erase operation of the memory cell array 20 in FIG. 1 by generating gate induced drain leakage GIDL.

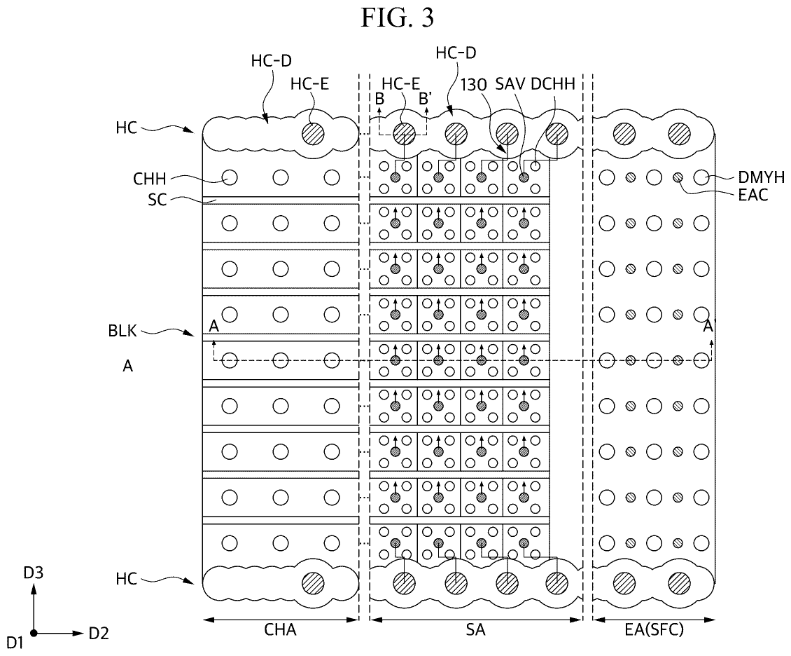

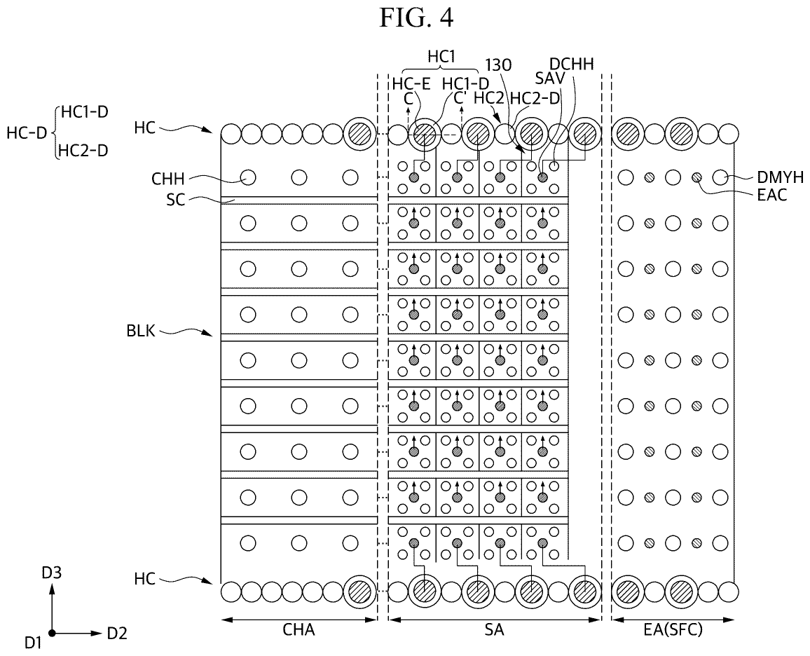

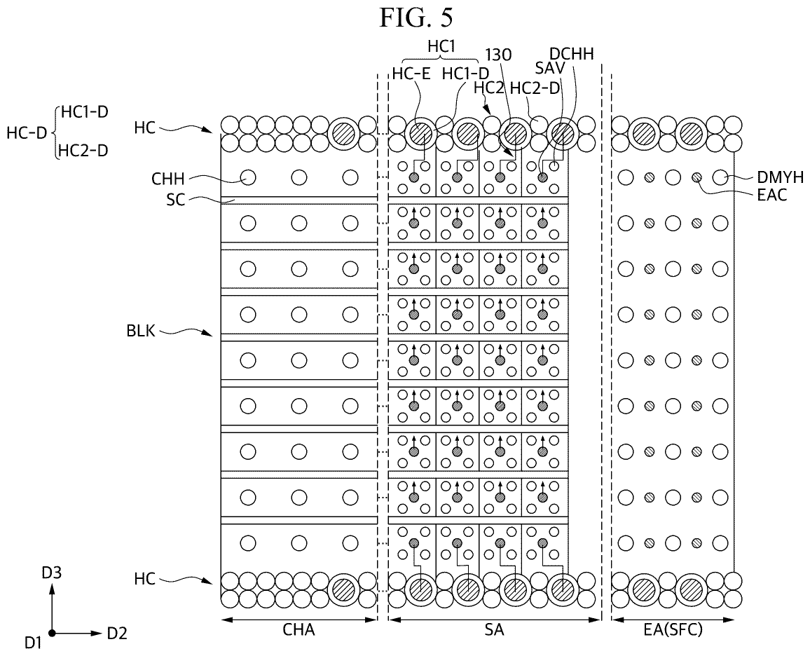

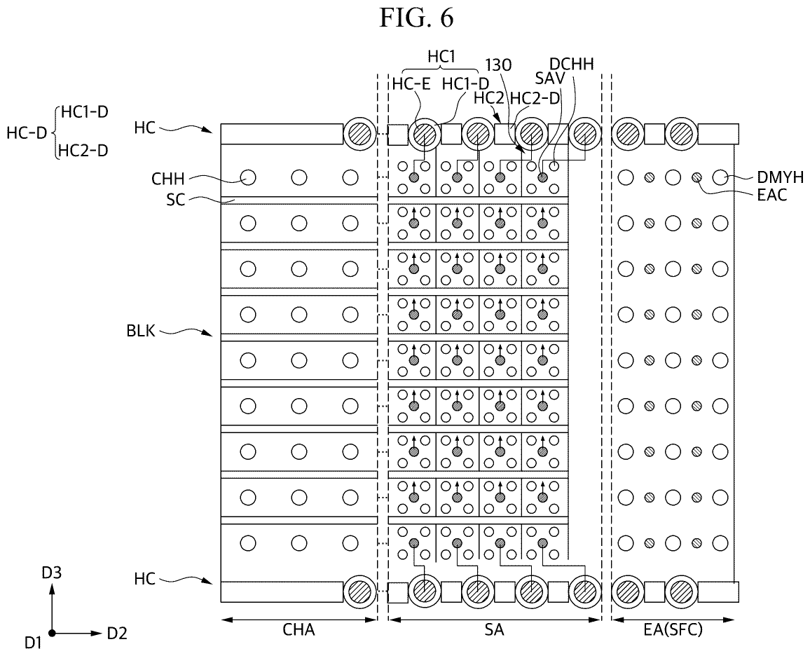

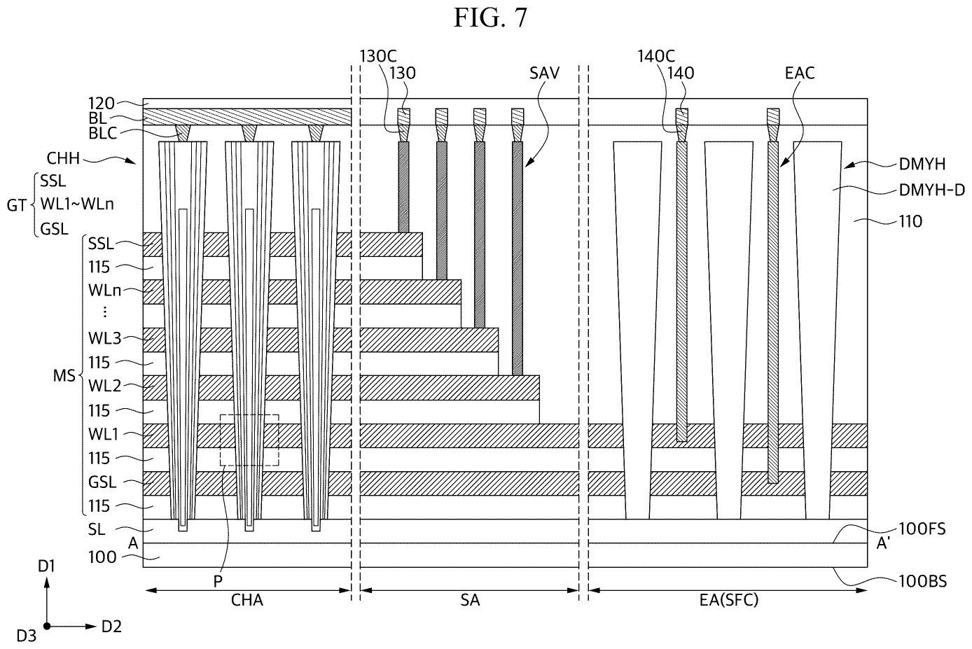

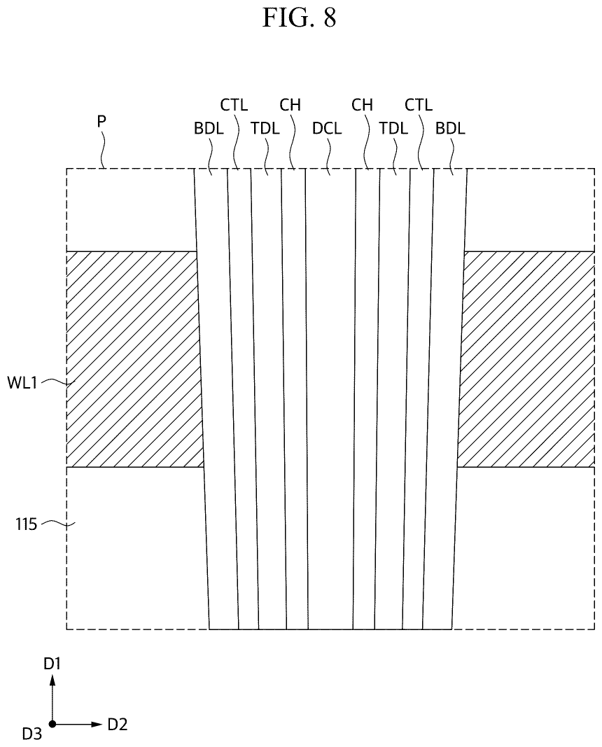

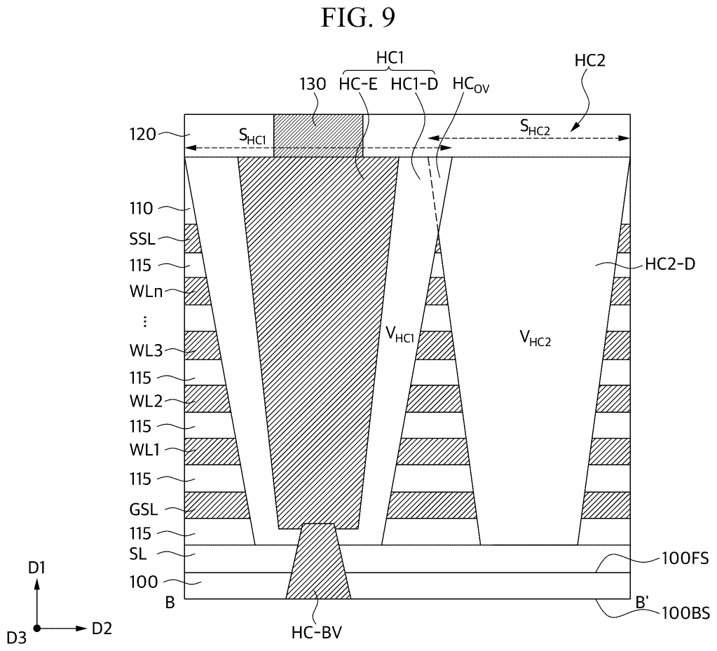

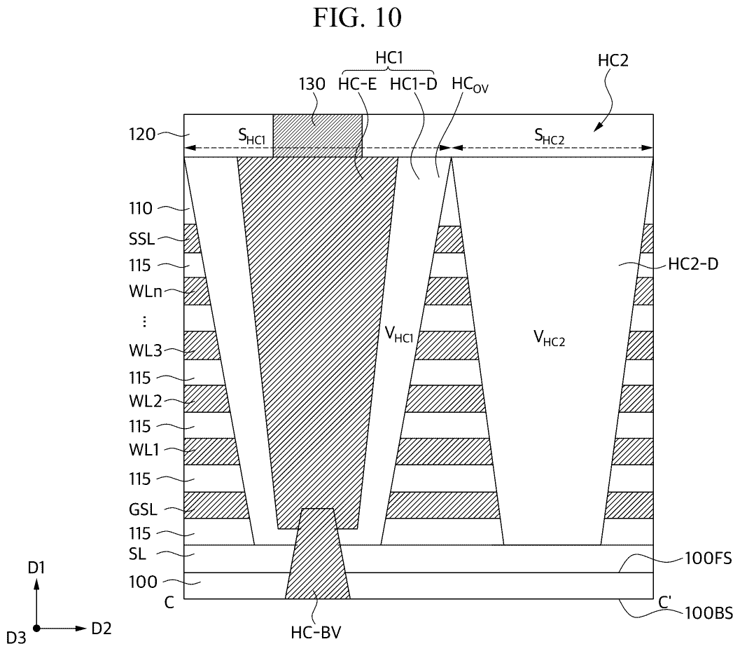

FIG. 3 is a plan view illustrating the semiconductor memory device 10 according to some example embodiments. FIG. 4 is a plan view illustrating the semiconductor memory device 10 according to some example embodiments. FIG. 5 is a plan view illustrating the semiconductor memory device 10 according to some example embodiments. FIG. 6 is a plan view illustrating the semiconductor memory device 10 according to some example embodiments. FIG. 7 is a cross-sectional view taken along line A-A′ of FIG. 3. FIG. 8 is an enlarged view of a portion P of FIG. 7. FIG. 9 is a cross-sectional view taken along line B-B′ of FIG. 3. FIG. 10 is a cross-sectional view taken along line C-C′ of FIG. 4.

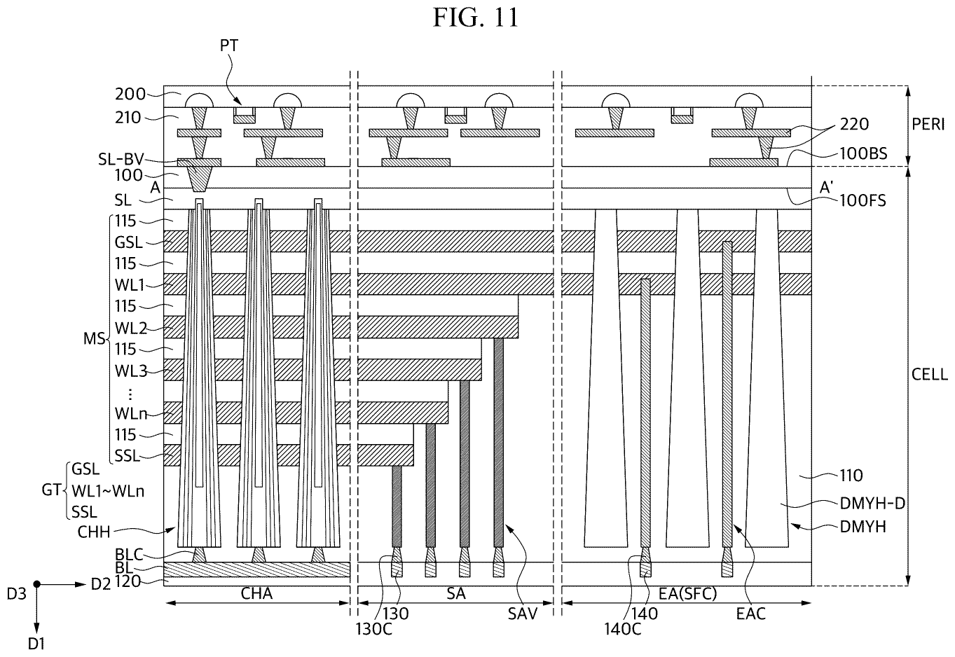

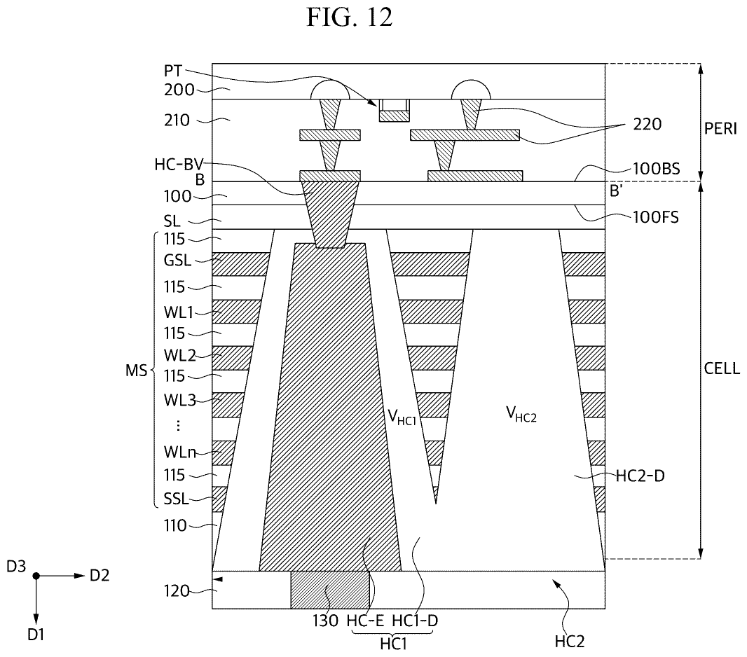

In some example embodiments, the semiconductor memory device 10 may include a cell region (a cell region CELL of FIG. 11 and a cell region CELL FIG. 12) and a peripheral circuit region (a peripheral circuit region PERI of FIG. 11 and a peripheral circuit region PERI FIG. 12) disposed on the cell region (the cell region CELL of FIG. 11 and the cell region CELL FIG. 12). Here, the cell region (the cell region CELL of FIG. 11 and the cell region CELL FIG. 12) may correspond to the memory cell array 20 described above, and the peripheral circuit region (the peripheral circuit region PERI of FIG. 11 and the peripheral circuit region PERI FIG. 12) may correspond to the peripheral circuit 30 described above.

The cell region (the cell region CELL of FIG. 11 and the cell region CELL FIG. 12) may be described first.

In some example embodiments, the semiconductor memory device 10 may include a cell substrate 100, a hole cut structure HC, and the memory cell block BLK.

In some example embodiments, the cell substrate 100 may include a semiconductor substrate, such as, for example, one or more of a silicon substrate, a germanium substrate and a silicon-germanium substrate. In some example embodiments, the cell substrate 100 may include a silicon-on-insulator (SOI) substrate and/or a germanium-on-insulator (GOI) substrate. In some cases, the cell substrate 100 may contain impurities. For example, the cell substrate 100 may contain one or more of n-type impurities, such as nitrogen (N), phosphorus (P) and arsenic (As), and/or may include one or more of p-type impurities such as boron (B), aluminum (Al), gallium (Ga) and indium (In).

Unless otherwise stated, the first direction D1 may indicate a direction perpendicular to a front side 100FS of the cell substrate. The second direction D2 may intersect (for example, be perpendicular) to the first direction D1. The second direction D2 may indicate, for example, a direction that is parallel to the front side 100FS of the cell substrate. The third direction D3 may intersect (for example, be perpendicular) to the first direction D1 and the second direction D2. The third direction D3 may indicate, for example, a direction that is horizontal to the front side 100FS of the cell substrate and intersects the second direction D2.

In some example embodiments, the cell substrate 100 may include a channel region CHA and a stair region SA. The channel region CHA and the stair region SA may be arranged sequentially based on the second direction D2. The cell substrate 100 may include the channel region CHA, the stair region SA and an extension region EA. The channel region CHA, the stair region SA and the extension region EA may be arranged sequentially based on the second direction D2.

In some example embodiments, the hole cut structure HC may be placed on the front side 100FS of the cell substrate. The hole cut structure HC may be arranged to extend in the second direction D2. There may be a plurality of hole cut structures HC, and the plurality of hole cut structures HC may be arranged spaced apart from each other. For example, the plurality of hole cut structures HC may be arranged spaced apart from each other in the third direction D3.

In some example embodiments, the memory cell block BLK may be placed between a plurality of hole cut structures HC that are spaced apart from each other. For example, when viewed in the first direction D1, the memory cell block BLK may be arranged in a planar shape extending in the second direction D2 and the third direction D3 between adjacent hole cut structures HC spaced apart from each other based on the third direction D3.

In some example embodiments, the memory cell block BLK may be placed on the front side 100FS of the cell substrate. Unless otherwise described, the front side 100FS of the cell substrate may indicate one side of the cell substrate 100 on which the memory cell block BLK is arranged. A back side 100BS of the cell substrate may indicate the opposite side (for example, the opposite side based on the first direction D1) of the surface of the cell substrate 100 on which the memory cell block BLK is arranged.

In some example embodiments, the memory cell block BLK may include mold structure MS including a gate electrode GT. The gate electrode GT may be stacked with spacing from each other in the first direction D1 on the channel region CHA and the stair region SA of the front side 100FS of the cell substrate. The mold structure MS may be disposed on the channel region CHA and the stair region SA of the front side 100FS of the cell substrate.

In some example embodiments, the semiconductor memory device 10 may include a string isolation structure SC disposed within the mold structure MS. The string isolation structure SC may be extended in the second direction D2 to truncate the string select line SSL. The memory cell block BLK may be divided by the string isolation structure SC to form multiple string regions. There may be a plurality of string isolation structures SC, and the plurality of string isolation structures SC may be spaced apart from each other in the third direction D3.

In some example embodiments, the gate electrode GT may be laminated in a stair-like manner in the stair region SA. The gate electrode GT may include a conductive material, for example, one or more of tungsten (W), molybdenum (Mo), nickel (Ni) and cobalt (Co).

In some example embodiments, the gate electrode GT may have a layered structure extending parallel to the front side 100 FS of the cell substrate. The gate electrode GT may be arranged to extend, for example, in the second direction D2.

In some example embodiments, the gate electrode GT in the stair region SA be laminated in a stair-like manner by forming steps, for example by varying the length extended in the second direction D2. In some example embodiments, in the stair region SA, the gate electrode GT may have a stair in the first direction D1.

In some example embodiments, the gate electrode GT may include the ground select line GSL, a plurality of word lines (WL1, WL2, WL3, . . . WLn) and the string select line SSL, which are sequentially laminated on the front side 100FS of the cell substrate. Referring to FIG. 7, only one ground select line GSL and only one string select line SSL are shown, but their number is not specifically limited. Further, even though the erase control line ECL in FIG. 2 is omitted, but the erase control line ECL is not limited thereto.

In some example embodiments, the memory cell block BLK may include a mold insulating layer 115 arranged in a space between the gate electrodes GT that are stacked and spaced apart from each other. For example, the gate electrode GT may be sequentially stacked on the front side 100FS of the cell substrate, separated from each other by the mold insulating layer 115. The mold insulating layer 115 may include an insulating material, and may include, for example, one or more of silicon oxide, silicon oxynitride and a low-k material.

A material composition and/or a thickness of each of the mold insulating layers 115 between each of the word lines WL may be the same; alternatively, at least one mold insulating layers 115 between each of the word lines WL may have a different thickness and/or a different material composition than at least another of the mold insulating layers 115 between each of the word lines WL. Alternatively or additionally, a material composition and/or a thickness of each of the word lines WL between each of the mold insulating layers 115 may be the same; alternatively, at least one of the word lines WL between each of the mold insulating layers 115 may have a different material composition and/or thickness that at least another of the word lines WL between each of the mold insulating layers 115.

In some example embodiments, the semiconductor memory device 10 may include a cell insulating layer 110 disposed on the front side 100FS of a cell substrate and surrounding at least a portion of the mold structure MS. The cell insulating layer 110 may include an insulating material, and may include, for example, one or more of silicon oxide, silicon oxynitride and a low-k material. The above described mold insulating layer 115 may be a part of the cell insulating layer 110. The cell insulating layer 110 may be formed along the channel region CHA, the stair region SA, and the extension region EA.

In some example embodiments, the memory cell block BLK may include a channel structure CHH penetrating at least a portion of the mold structure MS in the first direction D1 in the channel region CHA. For example, the channel structure CHH may have a pillar shape (for example, a cylinder shape) extending in the first direction D1. The channel structure CHH may intersect the gate electrode GT by penetrating the mold structure MS. In some example embodiments, the channel structure CHH may gradually decrease in width along the second direction D2 as the channel structure CHH approaches the cell substrate 100.

In some example embodiments, the number and/or the arrangement of the channel structures CHH when viewed in the first direction D1 are not particularly limited. FIG. 3 to FIG. 6 illustrate that the channel structure CHH is arranged parallel along the second direction D2, but the arrangement is not limited thereto. For example, the channel structure CHH may be arranged in a zigzag shape or a honeycomb shape by being alternated in the second direction D2 and the third direction D3.

Referring to FIG. 8, the channel structure CHH may include a channel layer CH and a charge trap layer CTL. The channel structure CHH may include the channel layer CH and the charge trap layer CTL, as well as a block insulating layer BDL, a tunnel insulating layer TDL and an insulation core layer DCL.

In some example embodiments, the charge trap layer CTL may surround the side surface of the channel layer CH. The charge trap layer CTL may be closer to the gate electrode GT than the channel layer CH. For example, referring to FIG. 8, the gate electrode GT may include the word line WL1. The charge trap layer CTL may include an insulating material, and may include, for example, one or more of silicon oxynitride, silicon nitride, germanium oxynitride, germanium nitride and a high-k material. The charge trap layer CTL may have multiple crystal defects. The charge trap layer CTL may perform a memory function that may store the data DATA by capturing charges by the voltage applied to the gate electrode GT.

In some example embodiments, the channel layer CH may include one or more of polysilicon such as doped or undoped polysilicon, indium oxide, tin oxide, zinc oxide, In—Zn (zinc) oxide (IZO), Sn(tin)—Zn oxide, Al(aluminum)—Zn oxide, Zn—Mg(magnesium) oxide, Sn—Mg oxide, In—Mg oxide, In—Ga oxide (IGO), In—Ga—Zn oxide (IGZO), In—Al—Zn oxides, In—Sn—Zn oxides, Sn—Ga—Zn oxides, Al—Ga—Zn oxides, Sn—Al—Zn oxides, In—Hf(hafnium)—Zn oxides, In—La(lanthanum)—Zn oxides, In—Ce(cerium)—Zn oxides, In—Pr(praseodymium)—Zn oxides, In—Nd(neodymium)—Zn oxides, In—Sm(samarium)—Zn oxides, In—Eu(europium)—Zn oxides, In—Gd(gadolinium)—Zn oxides, In—Tb(terbium)—Zn oxides, In—Dy(dysprosium)—Zn oxides, In—Ho(holmium)—Zn oxides, In—Er(erbium)—Zn oxides, In—Tm(thulium)—Zn oxides, In—Yb(ytterbium)—Zn oxides, In—Lu(ruthenium)—Zn oxides, In—Sn—Ga—Zn oxides, In—Hf—Ga—Zn oxides, In—Al—Ga—Zn oxides, In—Sn—Al—Zn oxides, In—Sn—Hf—Zn oxides, and In—Hf—Al—Zn oxides. However, the channel layer CH is not limited thereto.

In some example embodiments, the source line SL may be placed on the front side 100FS of the cell substrate, and may be placed between the cell substrate 100 and the ground select line GSL. A portion of the channel layer CH may come into contact with the source line SL. Referring to FIG. 7, a lower surface of the channel layer CH may be formed to protrude closer to the cell substrate 100 than a lower surface of the charge trap layer CTL.

In some example embodiments, in order for the channel structure CHH to be placed between the bit line BL and the source line SL, the bit line BL may be placed on the front side 100FS of the cell substrate. The channel structure CHH may be electrically connected to the bit line BL. In other words, the channel layer CH may be electrically connected to the bit line BL. The semiconductor memory device 10 may include a bit line contact BLC including a conductive material to connect between the bit line BL and the channel layer CH, if desired. Referring to FIG. 7, the bit line BL may also be extended in the second direction D2.

In some example embodiments, the semiconductor memory device 10 may include a cell interconnection insulating layer 120 surrounding at least a portion of the bit line BL. The cell interconnection insulating layer 120 may include an insulating material, and may include, for example, one or more of silicon oxide, silicon oxynitride. and a low-k material.

In some example embodiments, the channel layer CH may perform a channel function that electrically connects the source line SL and the bit line BL, which will be described later, when voltage is applied to the gate electrode GT.

In some example embodiments, the block insulating layer BDL may be placed between the gate electrode GT and the charge trap layer CTL. The block insulating layer BDL may surround the side surface of the charge trap layer CTL. The block insulating layer BDL may perform the function of reducing or minimizing the back tunneling phenomenon in which charges return from the gate electrode GT to the charge trap layer CTL. The block insulating layer BDL may include, for example, one or more of aluminum oxide, tin oxide, silicon nitride and a high-k material, but the block insulating layer BDL is not limited thereto.

In some example embodiments, the tunnel insulating layer TDL may be placed between the channel layer CH and the charge trap layer CTL. The tunnel insulating layer TDL may surround the side surface of the channel layer CH, and the charge trap layer CTL may surround the side surface of the tunnel insulating layer TDL. The tunnel insulating layer TDL may form a potential barrier between the channel layer CH and the charge trap layer CTL. The tunnel insulating layer TDL may include an insulating material, and may include, for example, one or more of silicon oxide, silicon nitride and silicon oxynitride.

In some example embodiments, the insulation core layer DCL may be surrounded by the channel layer CH. For example, the insulation core layer DCL may be placed within the channel layer CH. The insulation core layer DCL may contain an insulating material, and may include, for example, one or more of silicon oxide, silicon nitride and silicon oxynitride.

A thickness of each of the block insulating layer BDL, the charge trap layer CTL, the tunnel insulating layer TDL, the channel layer CH, and the insulating core layer DCL may be the same as each other; alternatively, a thickness of at least one of the block insulating layer BDL, the charge trap layer CTL, the tunnel insulating layer TDL, the channel layer CH, and the insulating core layer DCL may be different than a thickness of at least another of the block insulating layer BDL, the charge trap layer CTL, the tunnel insulating layer TDL, the channel layer CH, and the insulating core layer DCL.

In some example embodiments, the memory cell block BLK may include a stair region via SAV connected to the gate electrode GT stacked in a stair shape in the stair region SA and extending in the first direction D1. The stair region via SAV may contain conductive material, and may include, for example, one or more of tungsten (W), molybdenum (Mo), nickel (Ni) and cobalt (Co).

In some example embodiments, in order to be connected to the gate electrode GT that is stacked in a stair shape, the stair region via SAV may penetrate a part of the cell insulating layer 110 in the first direction D1.

In some example embodiments, there may be a plurality of stair region vias SAV, and each of the plurality of stair region vias SAV may correspond with each of the gate electrodes GT stacked in a stair shape, one-to-one. The number of stair region vias SAV is not particularly limited, but may be arranged more than the number of gate electrodes GT stacked in the stair shape.

In some example embodiments, in some cases, the stair region via SAV may pass through the gate electrode GT laminated in a stair shape. The stair region via SAV may penetrate the gate electrode GT laminated in a stair shape and not contact the source line SL.

In some example embodiments, the memory cell block BLK may include a dummy channel structure DCHH separated from the stair region via SAV in the stair region SA. The dummy channel structure DCHH may contain insulating material. The dummy channel structure DCHH may penetrate a part of the cell insulating layer 110 in the first direction D1. The dummy channel structure DCHH may help in the formation of the stair region via SAV. The dummy channel struct DCHH may not be electrically active during operation of the semiconductor memory device 10.

In some example embodiments, the semiconductor memory device 10 may include an extension region contact EAC penetrating at least a portion of the cell insulating layer 110 in the first direction D1 in the extension region EA. Specifically, the memory cell block BLK may include the extension region contact EAC in the extension region EA. The extension region EA may have the gate electrode GT that is not formed in a stair-like shape, and may be called a stair free region SFC, indicating that the stair-shaped structure is not formed.

In some example embodiments, the extension region contact EAC may contain conductive material. For example, the extension region contact EAC may contain one or more of tungsten (W), molybdenum (Mo), nickel (Ni) and cobalt (Co).

In some example embodiments, the extension region contact EAC may be connected to the gate electrode GT. The extension region contact EAC may not completely penetrate the gate electrode GT placed in the extension region EA. The extension region contact EAC may not contact the source line SL by penetrating the gate electrode GT placed in the extension region EA.

In some example embodiments, the semiconductor memory device 10 may include a dummy structure DMYH filled with a dummy structure insulating layer DMYH-D. Specifically, the memory cell block BLK may include the dummy structure DMYH filled with the dummy structure insulating layer DMYH-D in the extension region EA. The dummy structure DMYH may penetrate at least a portion of the cell insulating layer 110 in the first direction, but the dummy structure DMYH and the cell insulating layer 110 may not be distinguished. The dummy structure insulating layer DMYH-D may include an insulating material.

In some example embodiments, the dummy structure DMYH may penetrate the gate electrode GT placed in the extension region EA in the first direction D1. There may be a plurality of dummy structures DMYH. The plurality of dummy structures DMYH may be placed apart from the extension region contact EAC (for example, the second direction D2). In some example embodiments, each of the plurality of dummy structures DMYH may be filled with the dummy structure insulating layer DMYH-D.

In some example embodiments, the semiconductor memory device 10 may include a connection structure 130 including a conductive material. The connection structure 130 may in some example embodiments include one or more of tungsten (W), molybdenum (Mo), nickel (Ni) and cobalt (Co).

In some example embodiments, the cell interconnection insulating layer 120 may surround at least a portion of the connection structure 130. The connection structure 130 may be placed on the front side 100FS of the cell substrate. The stair region via SAV may be electrically connected to the connection structure 130. The semiconductor memory device 10 may include a connecting structure contact 130C including a conductive material to connect between the connection structure 130 and the stair region via SAV, if desired.

In some example embodiments, the hole cut structure HC may penetrate at least a portion of the mold structure MS in the first direction D1. For example, the hole cut structure HC may have a filler shape (for example, a cylindrical shape) extending in the first direction D1. In some example embodiments, the hole cut structure HC may gradually decrease in width along the second direction D2 as the hole cut structure HC approaches the cell substrate 100.

In some example embodiments, each of the plurality of hole cut structures HC that are spaced apart from each other may include a hole cut conductive layer HC-E and a hole cut insulating layer HC-D surrounding at least a portion of the hole cut conductive layer HC-E and extending in the second direction D2. The hole cut insulating layer HC-D may surround the side surface of the hole cut conductive layer HC-E.

In some example embodiments, the hole cut conductive layer HC-E may extend in the first direction D1. The hole cut conductive layer HC-E may gradually decrease in width along the second direction D2 as the hole cut conductive layer HC-E approaches the cell substrate 100.

In some example embodiments, the hole cut conductive layer HC-E may include a conductive material. For example, the hole cut conductive layer HC-E may include one or more of tungsten (W), molybdenum (Mo), nickel (Ni) and cobalt (Co). The hole cut insulating layer HC-D may include an insulating material, for example, one or more of silicon oxide, silicon oxynitride and a low-k material.

In some example embodiments, the hole cut conductive layer HC-E may be electrically connected to the connection structure 130. In order for the hole cut conductive layer HC-E to be placed between the connection structure 130 and the source line SL, the connection structure 130 may be placed on the front side 100FS of the cell substrate.

For example, the connection structure 130 may electrically connect the stair region via SAV and the hole cut conductive layer HC-E to each other. Through this, the performance of the semiconductor memory devices 10 may be improved by minimizing or reducing parasitic resistance by simplifying the interconnection structure. Alternatively or additionally, the integration density of the semiconductor memory devices 10 may be improved by minimizing or reducing the space required for the interconnection structure.

According to some example embodiments, it may possible to provide a semiconductor memory device and/or a method of manufacturing the semiconductor memory device by which performance is improved with simplifying an interconnection structure and reducing or minimizing parasitic resistance. Alternatively or additionally according to some example embodiments, it may be possible to provide a semiconductor memory device and/or a method of manufacturing the semiconductor memory device in which an integration density is improved with minimizing or reducing the space required due to the interconnection structure.

The effect of example embodiments are not limited to the above-described effects, and other effects not described would be clearly understood by those ordinary skill in the art.

In some example embodiments, the semiconductor memory device 10 may include a cell interconnection structure 140 including a conductive material. The cell interconnection structure 140 may specifically include one or more of tungsten (W), molybdenum (Mo), nickel (Ni) and cobalt (Co).

In some example embodiments, the cell interconnection insulating layer 120 may surround at least a portion of the cell interconnection structure 140. The cell interconnection structure 140 may be arranged on the front side 100FS of the cell substrate. The extension region contact EAC may be electrically connected to the cell interconnection structure 140. The semiconductor memory device 10 may include a cell interconnection contact 140C including a conductive material to connect between the cell interconnection structure 140 and the extension region contact EAC, if desired.

In some example embodiments, there may be a plurality of hole cut conductive layers HC-E. The plurality of hole cut conductive layers HC-E may be spaced apart from each other. For example, the plurality of hole cut conductive layers HC-E may be arranged spaced apart from each other in the second direction D2. In some example embodiments, when viewed in the first direction D1, the plurality of hole cut conductive layers HC-E may not be overlapping each other.

In some example embodiments, the hole cut structure HC may include a first hole cut structure HC1 and a second hole cut structure HC2. The first hole cut structure HC1 and the second hole cut structure HC2 may be distinguished based on the inclusion or absence of the hole cut conductive layer HC-E. Further, the first hole cut structure HC1 and the second hole cut structure HC2 may be distinguished based on their appearance and/or their size when viewed in the first direction D1.

In some example embodiments, there may be a plurality of first hole cut structures HC1. The second hole cut structure HC2 may be placed between adjacent first hole cut structures HC1 among the plurality of first hole cut structures HC1.

In some example embodiments, the first hole cut structure HC1 may include the hole cut conductive layer HC-E and a first hole cut insulating layer HC1-D surrounding at least a portion of the hole cut conductive layer HC-E. In some example embodiments, the second hole cut structure HC2 may be placed adjacent to the first hole cut structure HC1 and may include, e.g., may be filled with a second hole cut insulating layer HC2-D. In some example embodiments, the hole cut insulating layer HC-D may include the first hole cut insulating layer HC1-D and the second hole cut insulating layer HC2-D.

In some example embodiments, the first hole cut insulating layer HC1-D may surround all of or at least a portion of each of a side surface of the hole cut conductive layer HC-E and one surface of the hole cut conductive layer HC-E adjacent to the cell substrate 100. For example, the first hole cut insulating layer HC1-D may surround both the side surface of the hole cut conductive layer HC-E and the one surface of the hole cut conductive layer HC-E adjacent to the cell substrate 100.

In some example embodiments, when viewed in the first direction D1, the first hole cut structure HC1 may have a contact point with the second hole cut structure HC2. Through this, the hole cut structure HC may segment between the memory cell blocks BLK.

In some example embodiments, the volume V_{HC1} of the first hole cut structure HC1 may be greater than the volume V_{HC2} of the second hole cut structure HC2. Referring to FIG. 9 and FIG. 10, based on the appearance of the gate electrode (the ground select line GSL, the plurality of word lines WL1 to WLn, and the string select line SSL) penetrating through, the volume V_{HC1} of the first hole cut structure HC1 and the volume V_{HC2} of the second hole cut structure HC2 may be derived.

In some example embodiments, when viewed in the first direction D1, a surface area S_{HC1} of the first hole cut structure HC1 may be larger than a surface area S_{HC2} of the second hole cut structure HC2.

Referring to FIG. 3 and FIG. 9, the first hole cut structure HC1 and the second hole cut structure HC2 may overlap at a part. An overlapping region HC_{OV} may be formed between the first hole cut structure HC1 and the second hole cut structure HC2. When the first hole cut structure HC1 and the second hole cut structure HC2 overlap at a part, each of the volume V_{HC1} of the first hole cut structure HC1 and the volume V_{HC2} of the second hole cut structure HC2 may include the volume of the overlapping region HC_{OV}.

Referring to FIG. 3 and FIG. 9, when the first hole cut structure HC1 and the second hole cut structure HC2 overlap at a part, each of the surface S_{HC1} area of the first hole cut structure HC1 and the surface area S_{HC2} of the second hole cut structure HC2 may include a surface area of the overlapping region HC_{OV}.

Referring to FIG. 4 and FIG. 10, the first hole cut structure HC1 and the second hole cut structure HC2 may be arranged with one contact point.

In some example embodiments, when viewed in the first direction D1, the shape of the first hole cut structure HC1 may be identical to the shape of the second hole cut structure HC2. Referring to FIG. 3 to FIG. 5, when viewed in the first direction, the shape of the first hole cut structure HC1 and the shape of the second hole cut structure HC2 may be circular. Through this, the first hole cut structure HC1 and the second hole cut structure HC2 may be formed simultaneously or at least partly simultaneously. However, when viewed in the first direction D1, the shape of the first hole cut structure HC1 and the shape of the second hole cut structure HC2 is not limited to a circle. In some example embodiments the shape may be a polygon other than an ellipse or a rectangle.

In some example embodiments, when viewed in the first direction D1, the shape of the first hole cut structure HC1 may be different from the shape of the second hole cut structure HC2. Referring to FIG. 6, when viewed in the first direction D1, the shape of the first hole cut structure HC1 may be circular, and the shape of the second hole cut structure HC2 may be square. However, the shape of the first hole cut structure HC1 when viewed in the first direction D1 is not limited to a circle, and may be a polygon other than an ellipse or a rectangle. When the shape of the second hole cut structure HC2 is not a square, the shape of the first hole cut structure HC1 may be rectangular. Further, the shape of the second hole cut structure HC2 is not restricted to a rectangle when viewed in the first direction D1, and in some example embodiments may be circular, elliptical, or polygonal other than rectangular.

In some example embodiments, there may be a plurality of second hole cut structures HC2. At least some of the plurality of second hole cut structures HC2 may be arranged side by side in the second direction D2 or may be arranged side by side in the third direction D3. Referring to FIG. 5, the plurality of second hole cut structures HC2 may be placed between adjacent first hole cut structures HC1 among a plurality of first hole cut structures HC1. Here, the plurality of second hole cut structures HC2 may be arranged side by side along the third direction D3. However, the arrangement is not limited thereto. The plurality of second hole cut structures HC2 may be arranged side by side in the second direction D2, and may be arranged in the second direction D2 and the third direction D3, respectively. The plurality of second hole cut structures HC2 may have contact points with each other.

FIG. 11 is a cross-sectional view taken along line A-A′ of FIG. 3. FIG. 12 is a cross-sectional view taken along line B-B′ of FIG. 3. Referring to FIG. 11 and FIG. 12, as described above, the semiconductor memory device 10 may include the cell region CELL and the peripheral circuit region PERI arranged on the cell region CELL. Based on the cell substrate 100, the elements of the cell region CELL excluding the cell substrate 100 may be arranged on the front side 100FS of the cell substrate, and the elements of the peripheral circuit region PERI may be placed on the back side 100BS of the cell substrate.

In some example embodiments, the peripheral circuit region PERI may include a peripheral circuit insulating layer 210 disposed on the back side 100BS of the cell substrate. The peripheral circuit insulating layer 210 may include an insulating material, and may include, for example, one or more of silicon oxide, silicon oxynitride and a low-k material.

In some example embodiments, the peripheral circuit region PERI may include a peripheral circuit interconnection structure 220 disposed within the peripheral circuit insulating layer 210. The peripheral circuit interconnection structure 220 may include a conductive material. In some example embodiments, the peripheral circuit interconnection structure 220 may include one or more of tungsten (W), molybdenum (Mo), nickel (Ni) and cobalt (Co).

In some example embodiments, the peripheral circuit region PERI may be placed on the back side 100BS of the cell substrate and include a peripheral circuit substrate 200 supporting the peripheral circuit insulating layer 210. The peripheral circuit substrate 200 may include a semiconductor substrate, such as, for example, one or more of a silicon substrate, a germanium substrate and a silicon-germanium substrate. In some example embodiments, the peripheral circuit substrate 200 may include a silicon-on-insulator (SOI) substrate or a germanium-on-insulator (GOI) substrate. In some cases, the peripheral circuit substrate 200 may contain impurities. For example, the peripheral circuit substrate 200 may include one or more of n-type impurities such as nitrogen (N), phosphorus (P) and arsenic (As), and/or may include one or more of p-type impurities such as boron (B), aluminum (Al), gallium (Ga) and indium (In).

In some example embodiments, the peripheral circuit region PERI may include a peripheral circuit device PT arranged on the peripheral circuit substrate 200. The peripheral circuit device PT may form part of the peripheral circuit 30 of FIG. 1 that controls the operation of the semiconductor memory device 10. For example, the peripheral circuit device PT may include the control logic 37 of FIG. 1, the row decoder 33 of FIG. 1, and the page buffer 35 of FIG. 1. The peripheral circuit device PT may include, for example, but is not limited to, one or more transistors. For example, the peripheral circuit device PT may include various active elements such as transistors and/or diodes, as well as various passive elements such as capacitors, registers, and inductors. The peripheral circuit insulating layer 210 may surround the peripheral circuit device PT. The peripheral circuit interconnection structure 220 within the peripheral circuit insulating layer 210 may be connected to the peripheral circuit device PT.

In some example embodiments, the semiconductor memory device 10 may include a hole cut back side contact HC-BV including a conductive material. Specifically, referring to FIG. 9, FIG. 10 and FIG. 12, the cell region CELL may include the hole cut back side contact HC-BV. The hole cut back side contact HC-BV may include conductive material, and may include, for example, one or more of tungsten (W), molybdenum (Mo), nickel (Ni) and cobalt (Co).

In some example embodiments, the hole cut back side contact HC-BV may penetrate the cell substrate 100. Referring to FIG. 9, FIG. 10 and FIG. 12, the hole cut back side contact HC-BV may penetrate the cell substrate 100 in the first direction D1, and may further penetrate the cell substrate 100 and the source line SL in the first direction D1.

In some example embodiments, the hole cut back side contact HC-BV may electrically connect the peripheral circuit interconnection structure 220 and the hole cut conductive layer HC-E to each other. Through this, the interconnection structure may be simplified and parasitic resistance may be reduced or minimized, and thus the performance of the semiconductor memory device 10 may be improved. Alternatively or additionally, the integration density of the semiconductor memory devices 10 may be improved by minimizing or reducing the space required due to the interconnection structure.

For example, the hole cut conductive layer HC-E and the stair region via SAV may be electrically connected through the connection structure 130, and by the hole cut conductive layer HC-E and the peripheral circuit interconnection structure 220 being electrically connected through the hole cut back side contact HC-BV, ultimately, the stair region via SAV and the peripheral circuit interconnection structure 220 may be electrically connected. Through this, the interconnection structure may be simplified and parasitic resistance may be reduced or minimized, and thus the performance of the semiconductor memory device 10 may be improved. Alternatively or additionally, the integration density of the semiconductor memory devices 10 may be improved by reducing or minimizing the space required due to the interconnection structure.

In some example embodiments, the semiconductor memory device 10 may include a source back side contact SL-BV electrically connecting the source line SL and the peripheral circuit interconnection structure 220 to each other. The source back side contact SL-BV may contain conductive material, and may include, for example, one or more of tungsten (W), molybdenum (Mo), nickel (Ni) and cobalt (Co).

In some example embodiments, the source back side contact SL-BV may penetrate the cell substrate 100. Referring to FIG. 11, the source back side contact SL-BV may penetrate the cell substrate 100 in the first direction D1.

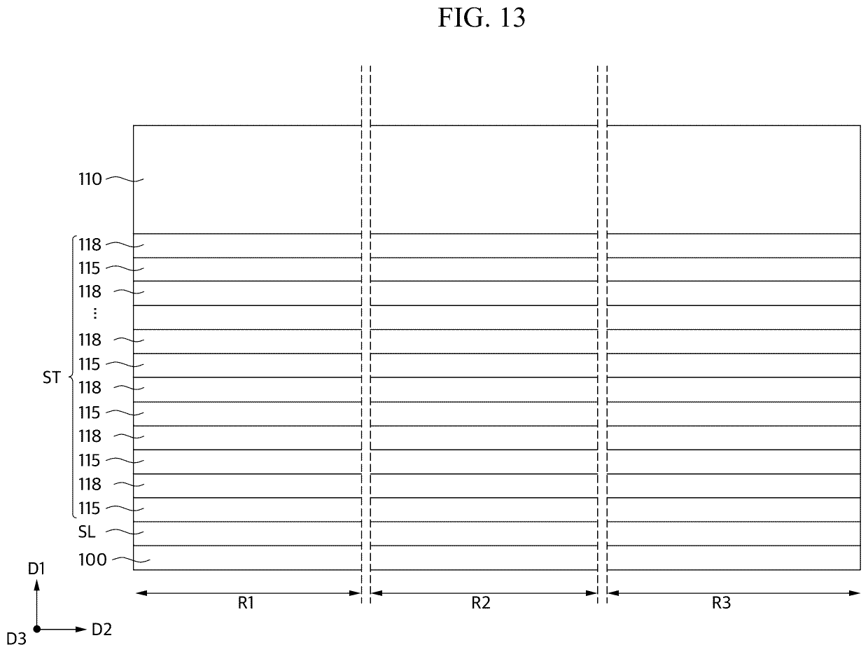

FIG. 13 to FIG. 33 are drawings for explaining a method of manufacturing the semiconductor memory device 10 according to some example embodiments. In some example embodiments, any method may be applied as long as it does not contradict the manufacturing method of the semiconductor memory device 10. Hereinafter, the method for securing the structural features of the aforementioned semiconductor memory device 10 is mainly explained.

As used herein, a specific layer is not limited specifically, but in some example embodiments, a specific layer may be formed through deposition. The deposition may be performed using, for example, one or more of chemical vapor deposition (CVD), physics vapor deposition (PVD), or atomic layer deposition (ALD). Other methods other than the deposition in forming a specific film and/or a specific layer may be applied. Further, as used herein, a specific film or a specific layer is not specifically limited but in some example embodiments, but a specific film or a specific layer in the present disclosure may be removed through etching. The etching may be performed, for example, by dry etching and/or by wet etching, for example, using phosphoric acid and/or hydrofluoric acid.

In some example embodiments, the cell substrate 100 may include a first region R1, a second region R2 and a third region R3. The first region R1 may refer to the region where the channel structure CHH is formed. The second region R2 may refer to the region where the first hole cut structure HC1 is formed. The third region R3 may refer to the region where the second hole cut structure HC2 is formed.

Referring to FIG. 13, the method of manufacturing the semiconductor memory device 10 may include forming a stacked structure ST in which the mold insulating layer 115 and a replacement insulating layer 118 are alternately laminated (e.g., deposited with a process such as but not limited to an ALD process) in the first direction D1 on the cell substrate 100. On the cell substrate 100, the source line SL may be formed. The stacked structure ST may be formed on the source line SL. The method of manufacturing the semiconductor memory device 10 may include forming the cell insulating layer 110 on the stacked structure ST. In some example embodiments, the replacement insulating layer 118 may include an insulating material, and may include an insulating material different from the material included in the mold insulating layer 115. For example, the mold insulating layer 115 may include silicon oxide, and the replacement insulating layer 118 may include silicon nitride.

In some example embodiments, the mold insulating layer 115 and the replacement insulating layer 118 may have a layered structure extending parallel to the cell substrate 100. For example, the mold insulating layer 115 and the replacement insulating layer 118 may be arranged to extend in the second direction D2 and be laminated in the first direction D1.

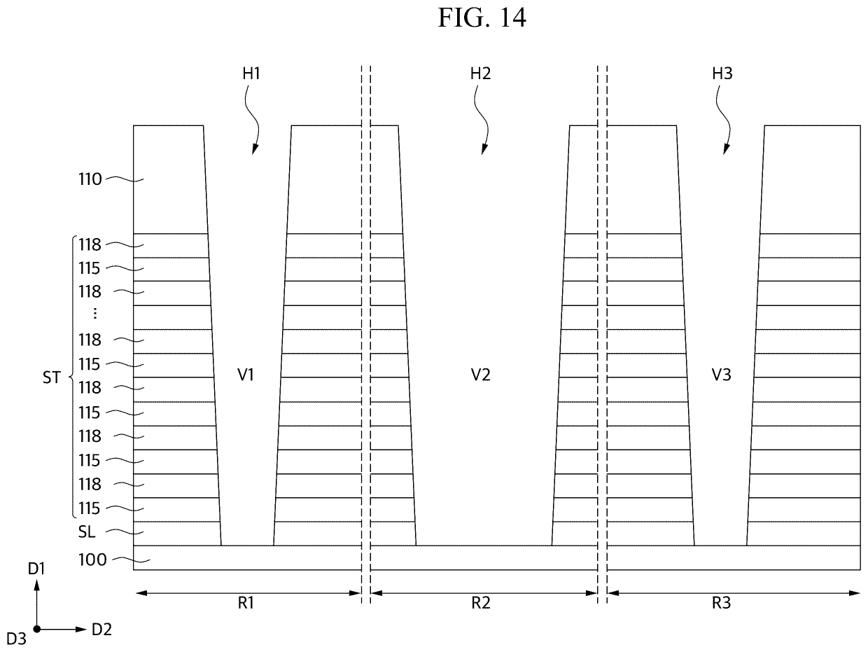

Referring to FIG. 14, the method of manufacturing the semiconductor memory device 10 may include forming a first hole H1 penetrating the stacked structure ST in the first region R1 in the first direction D1, forming a second hole H2 penetrating the stacked structure ST in the second region R2 in the first direction D1, and forming a third hole H3 penetrating the stacked structure ST in the third region R3 in the first direction D1. The forming the first hole H1, the forming the second hole H2, and the forming the third hole H3 may include an etching process, such as an isotropic etching process using a wet chemical and/or an anisotropic process using a dry etch; example embodiments are not limited thereto.

In some example embodiments, the method of manufacturing the semiconductor memory device 10 may include forming each of the first hole H1, the second hole H2 and the third hole H3 in order for the source line SL not to be penetrated.

In some example embodiments, the volume V2 of the formed second hole H2 may be larger than the volume V1 of the formed first hole H1. For example, the second hole H2 may be formed in order to be greater than the volume V1 of the first hole H1. In some cases, the volume V2 of the formed second hole H2 may be larger than the volume V3 of the formed third hole H3. In some cases, the volume V3 of the third hole H3 may be substantially equal to the volume V1 of the first hole H1. Here, being substantially equal may indicate that the ratio of the difference between the volume V3 of the third hole H3 and the volume V1 of the first hole H1 is within 5% based on the volume V3 of the third hole H3.

In some example embodiments, the first hole H1, the second hole H2, and the third hole H3 may be formed at the same time. Here, being formed at the same time may indicate that the first hole H1, the second hole H2 and the third hole H3 are all formed in one process.

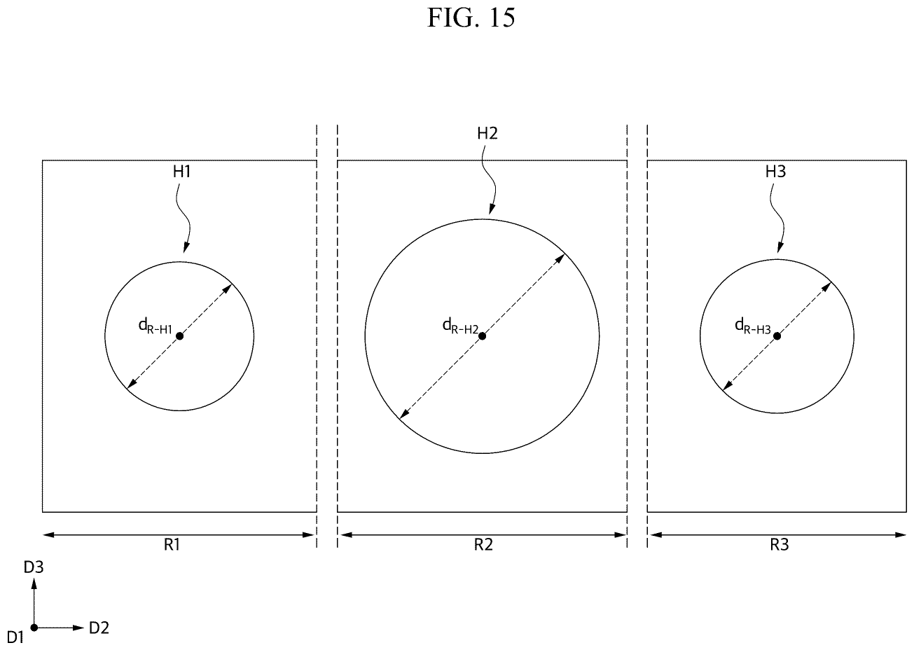

In some example embodiments, the shape of the first hole H1, the second hole H2 and the third hole H3 may be identical when viewed in the first direction D1. Referring to FIG. 15, the shape of the first hole H1, the second hole H2 and the third hole H3 may be circular when viewed in the first direction D1. For example, when the shape of the first hole H1, the second hole H2 and the third hole H3 is circular when viewed in the first direction D1, the diameter d_{R-H2} of the second hole H2 may be larger than the diameter d_{R-H1} of the first hole H1. Further, in this case, the diameter d_{R-H2} of the second hole H2 may be larger than the diameter d_{R-H3} of the third hole H3. Further, in this case, the diameter d_{R-H3} of the third hole H3 may be substantially the same as the diameter d_{R-H1} of the first hole H1. Here, being substantially the same may indicate that the ratio of the difference between the diameter of the third hole H3 d_{R-H3} and the diameter of the first hole H1 d_{R-H1} is within 5% based on the diameter of the third hole H3 d_{R-H3}.

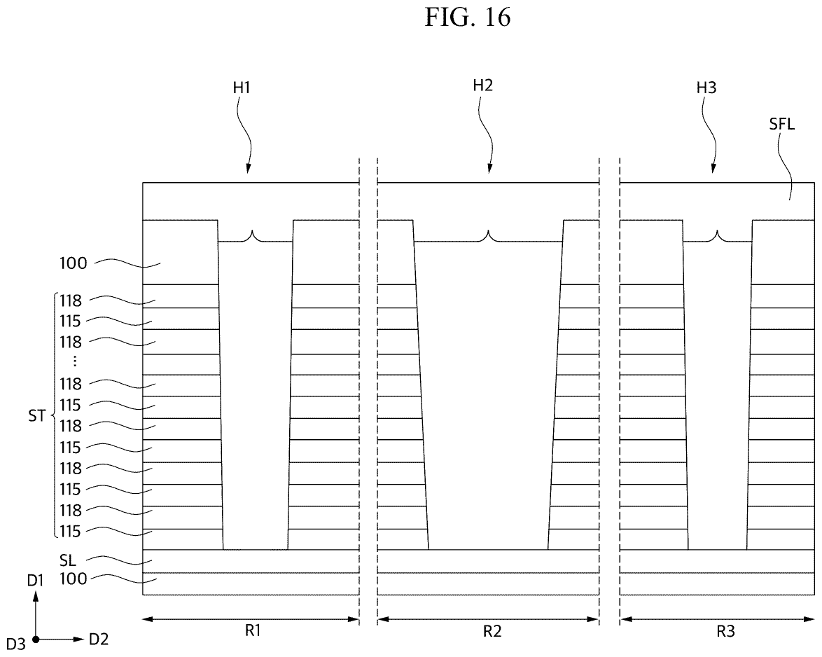

Referring to FIG. 16, the method of manufacturing the semiconductor memory device 10 may include forming a sacrificial layer SFL in order for each entrance of the first hole H1, the second hole H2 and the third hole H3 to be closed. The sacrificial layer SFL may contain materials with so-called low step coverage. The sacrificial layer SFL may contain, for example, carbon. The sacrificial layer SFL is formed of a material with low step coverage, so that only the entrance region may be closed without filling each of the first hole H1, the second hole H2 and the third hole H3.

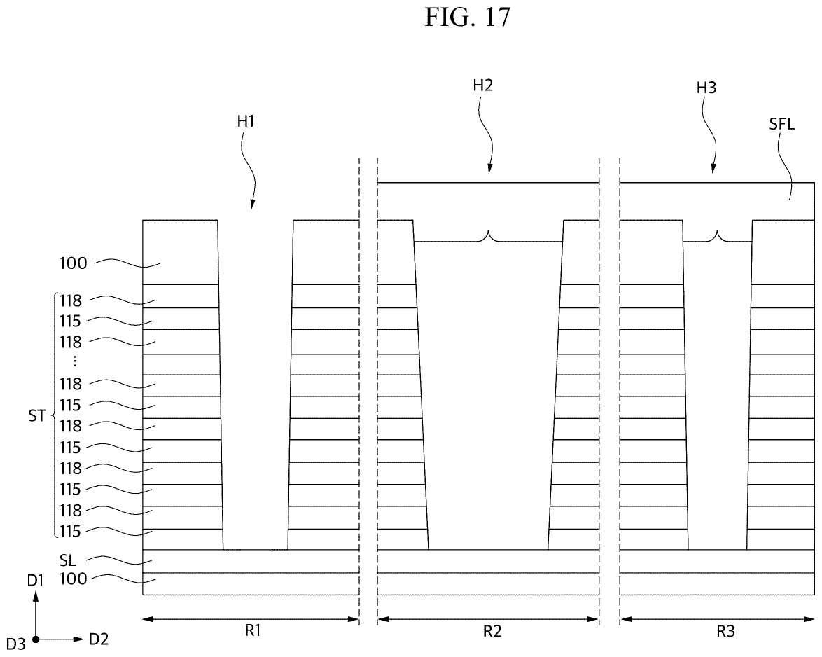

Referring to FIG. 17, the method of manufacturing the semiconductor memory device 10 may include removing the sacrificial layer SFL that is formed in the first region R1. The sacrificial layer SFL may be removed by a photo process.

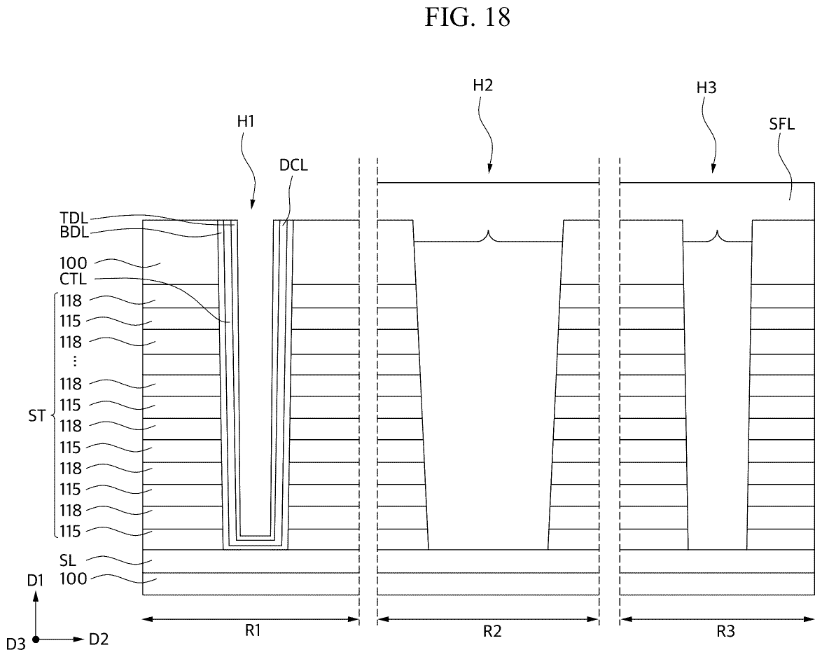

Referring to FIG. 18 to FIG. 20, the method of manufacturing the semiconductor memory device 10 may include forming the channel structure CHH in the first hole H1.

Referring to FIG. 18, the method of manufacturing the semiconductor memory device 10 may include forming the block insulating layer BDL, forming the charge trap layer CTL on the block insulating layer BDL, and forming the tunnel insulating layer TDL on the charge trap layer CTL.

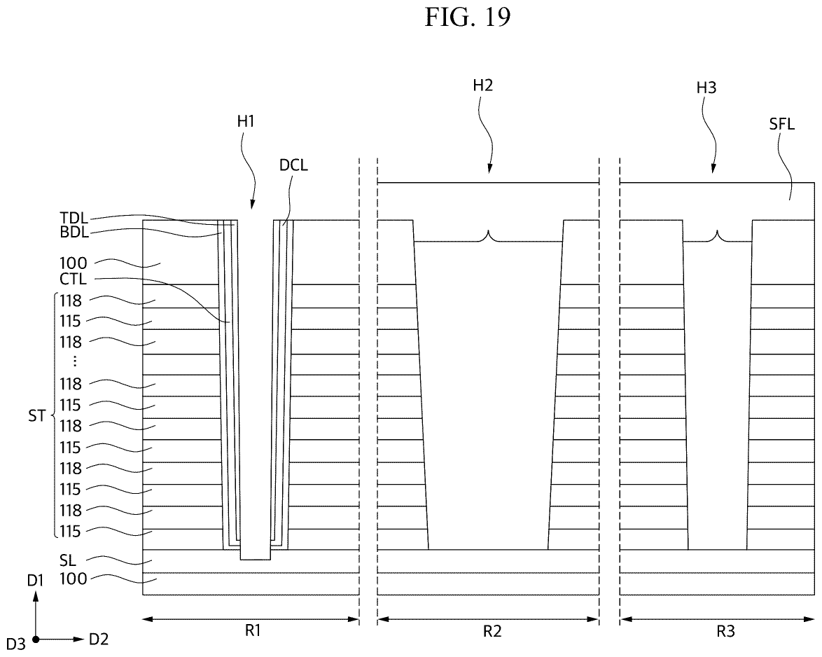

Referring to FIG. 19, the method of manufacturing the semiconductor memory device 10 may include etching the block insulating layer BDL, the charge trap layer CTL and the tunnel insulating layer TDL formed on the lower surface of the first hole H1 in order for the first hole H1 to penetrate a portion of the source line SL.

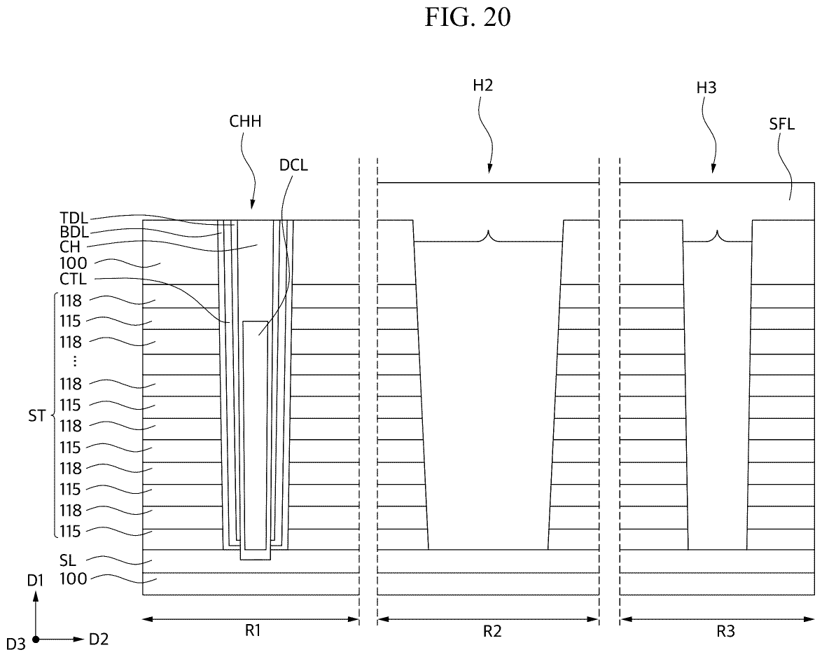

Referring to FIG. 20, the method of manufacturing the semiconductor memory device 10 may include forming the channel layer CH and the insulation core layer DCL. The channel layer CH may be formed to contact the source line SL. Although not shown separately in the drawing, a plurality of deposition layers may be formed on the cell insulating layer 110 in the process of forming the channel structure CHH. The method of manufacturing the semiconductor memory device 10 may include, after forming the channel structure CHH, removing several deposition layers formed on the cell insulating layer 110. Here, the plurality of deposition layers may be removed by, but are not limited to, chemical mechanical polishing (CMP) and/or etch-back.

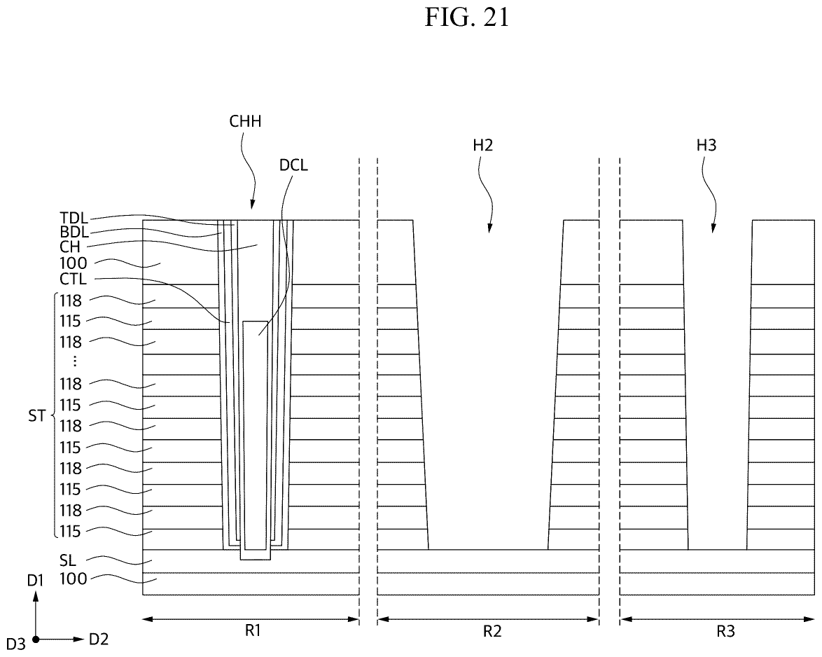

Referring to FIG. 21, the method of manufacturing the semiconductor memory device 10 may include removing the sacrificial layer SFL formed in the second region R2 and the third region R3. The sacrificial layer SFL may be removed by a photo process and/or an etch process such as a wet etching process.

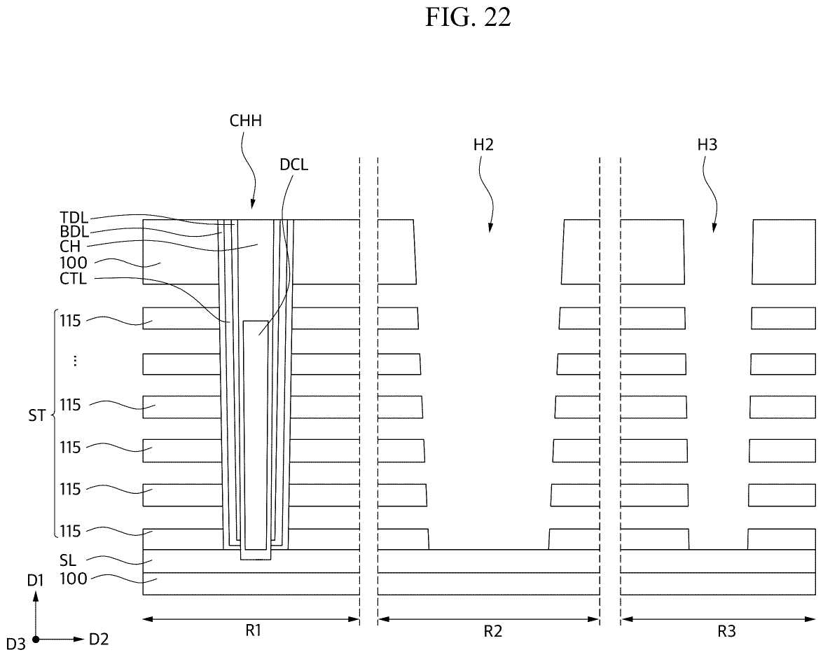

Referring to FIG. 22, the method of manufacturing the semiconductor memory device 10 may include removing the replacement insulating layer 118.

In some example embodiments, the method of manufacturing the semiconductor memory device 10 may include forming a stair structure on a part of the stacked structure ST before removing the replacement insulating layer 118. In some example embodiments, the mold insulating layer 115 and the replacement insulating layer 118 may form a stair by making the extended length in the second direction D2 different, so that a stair structure may be formed in part of the stacked structure ST. In other words, the stair structure may have stairs in the first direction D1.

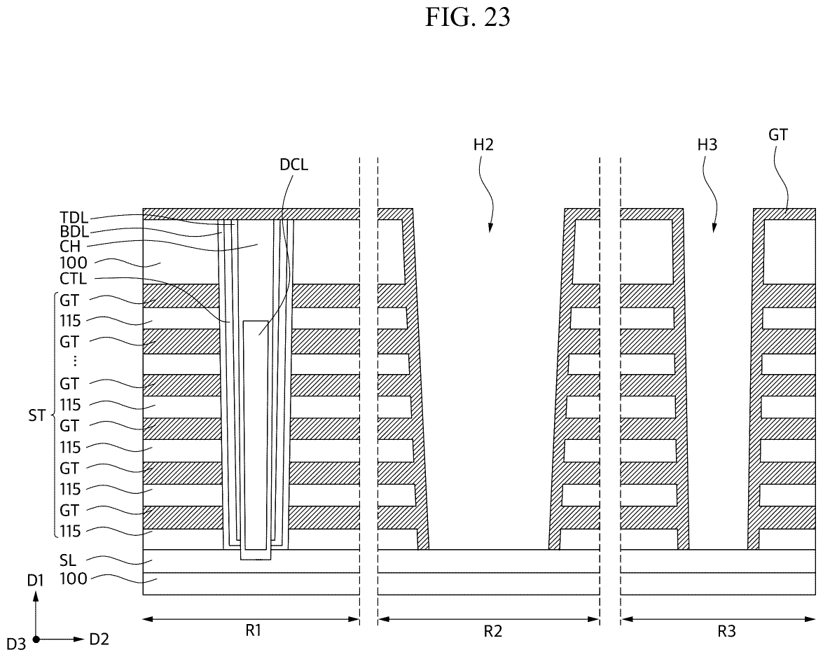

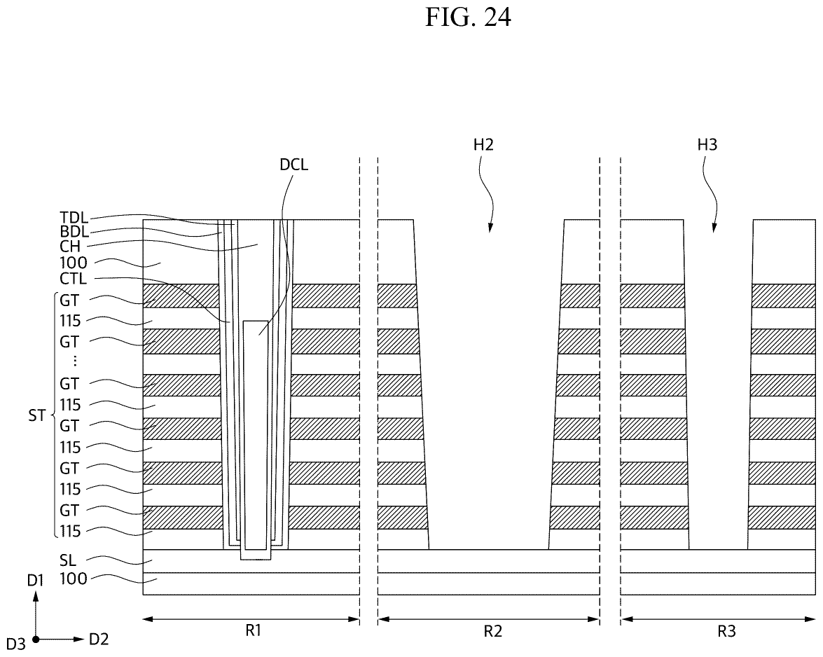

Referring to FIG. 23, the method of manufacturing the semiconductor memory device 10 may include forming the gate electrode GT at the location where the replacement insulating layer 118 is removed. Referring to FIG. 24, the method of manufacturing the semiconductor memory device 10 may include removing the gate electrode GT formed in the second hole H2 and the third hole H3. In some example embodiments, in the semiconductor memory device 10, after the gate electrode GT is formed, a stair region hole may be formed to expose the gate electrode GT arranged in the stair structure, and the stair region via SAV in FIG. 7 may be formed by filling the stair region hole with a conductive material.

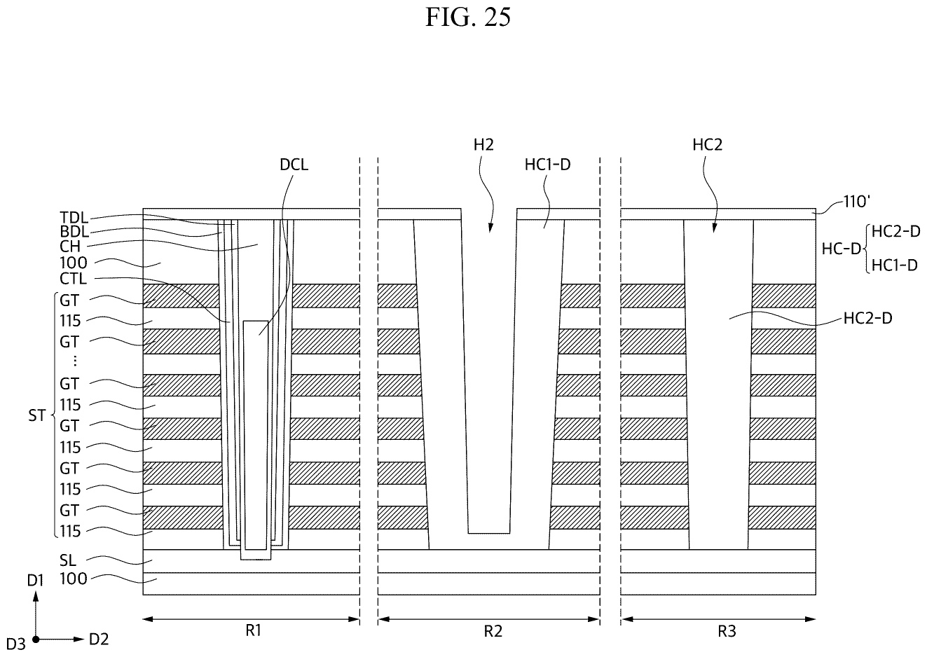

Referring to FIG. 25, the method of manufacturing the semiconductor memory device 10 may include forming an additional cell insulating layer 110′. The additional cell insulating layer 110′ may become a part of the cell insulating layer 110 in the future. The method of manufacturing the semiconductor memory device 10 may include forming the first hole cut insulating layer HC1-D in part of the second hole H2, and filling the second hole cut insulating layer HC2-D into the third hole H3. The first hole cut insulating layer HC1-D and the second hole cut insulating layer HC2-D may be formed through the additional cell insulating layer 110′. Referring to FIG. 14 and FIG. 15, by the second hole H2 being formed in order for the volume V2 of the second hole H2 to be greater than the volume V1 of the first hole H1, the first hole cut insulating layer HC1-D may not fill the second hole H2, there may be some empty region, and the second hole cut insulating layer HC2-D may fill the third hole H3. For example, the additional cell insulating layer 110′ may be formed such that at least the third hole H3 is completely filled.

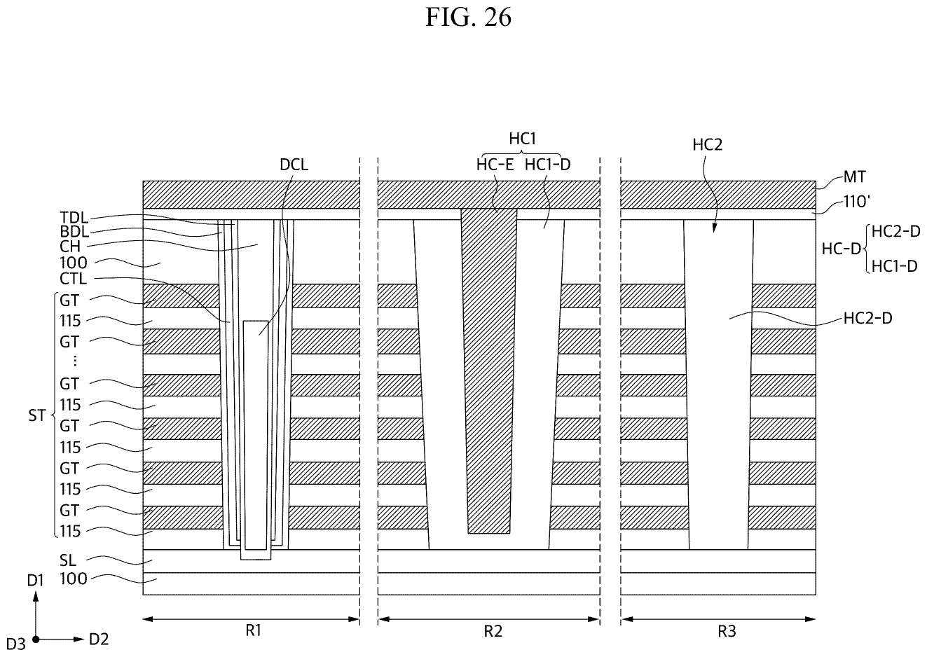

Referring to FIG. 26, the method of manufacturing the semiconductor memory device 10 may include forming a metal layer MT. The method of manufacturing the semiconductor memory device 10 may include forming the hole cut conductive layer HC-E on the first hole cut insulating layer HC1-D to fill the second hole H2. The hole cut conductive layer HC-E may be formed through the metal layer MT.

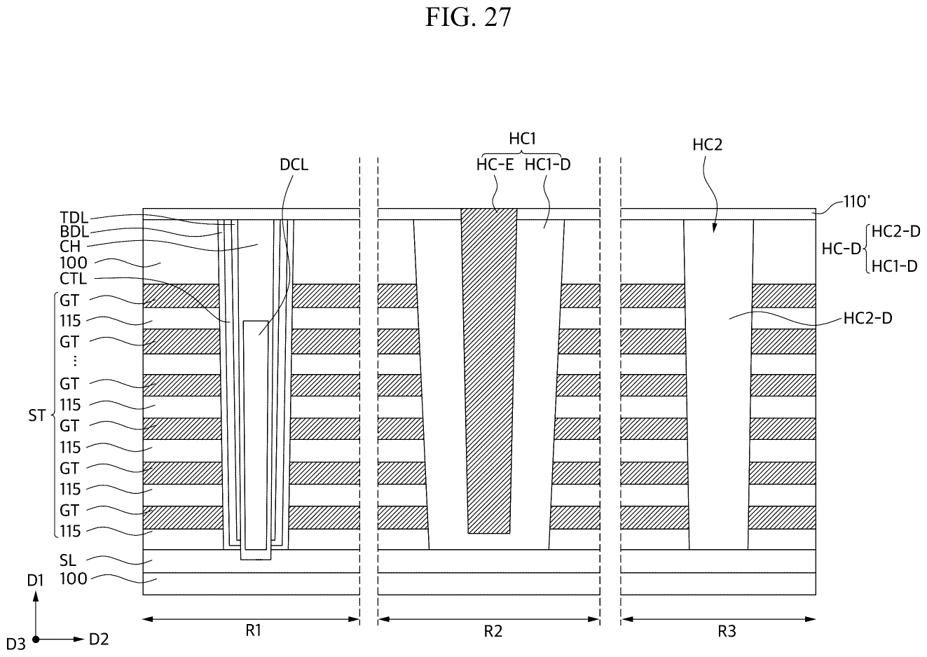

Referring to FIG. 27, the method of manufacturing the semiconductor memory device 10 may include removing the metal layer MT formed on the additional cell insulating layer 110′. Here, the metal layer MT may be removed by CMP and/or an etch-back process, but is not limited thereto.

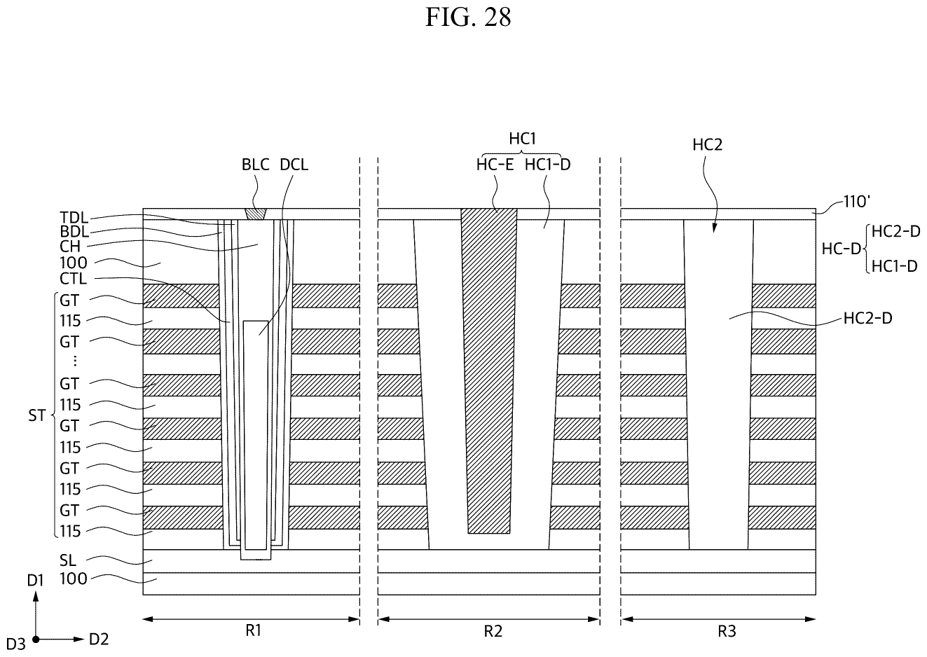

Referring to FIG. 28, the method of manufacturing the semiconductor memory device 10 may include forming the bit line contact BLC that is connected to the channel structure CHH and penetrates the additional cell insulating layer 110′. Specifically, the bit line contact BLC may be connected to the channel layer CH.

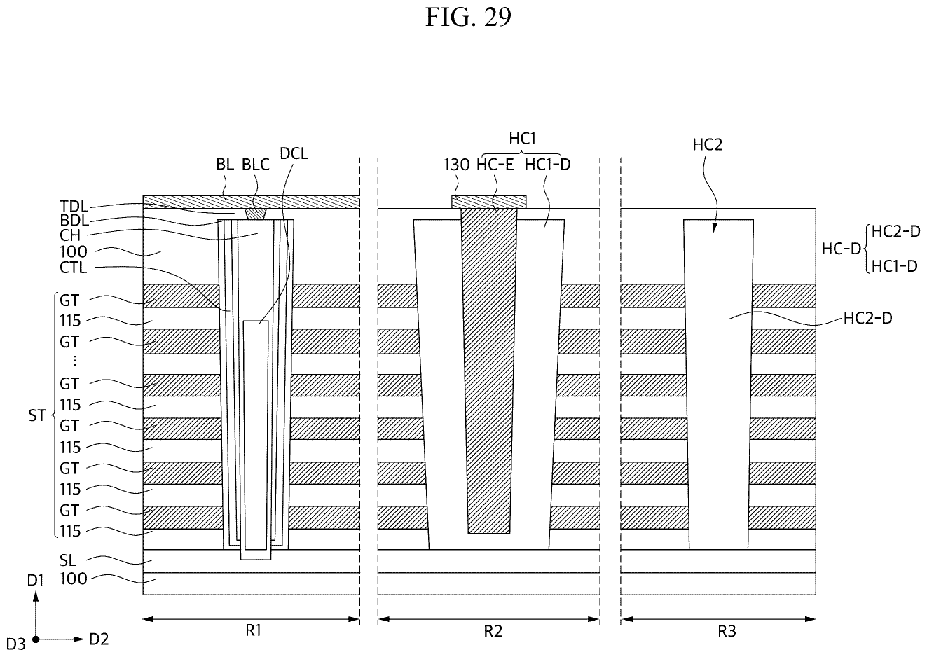

Referring to FIG. 29, the method of manufacturing the semiconductor memory device 10 may include forming the bit line BL that is electrically connected to the channel structure CHH and forming the connection structure 130 electrically connected to the hole cut conductive layer HC-E. In some example embodiments, the method of manufacturing the semiconductor memory device 10 may include electrically connecting the stair region via SAV in FIG. 7 and the hole cut conductive layer HC-E with the connection structure 130.

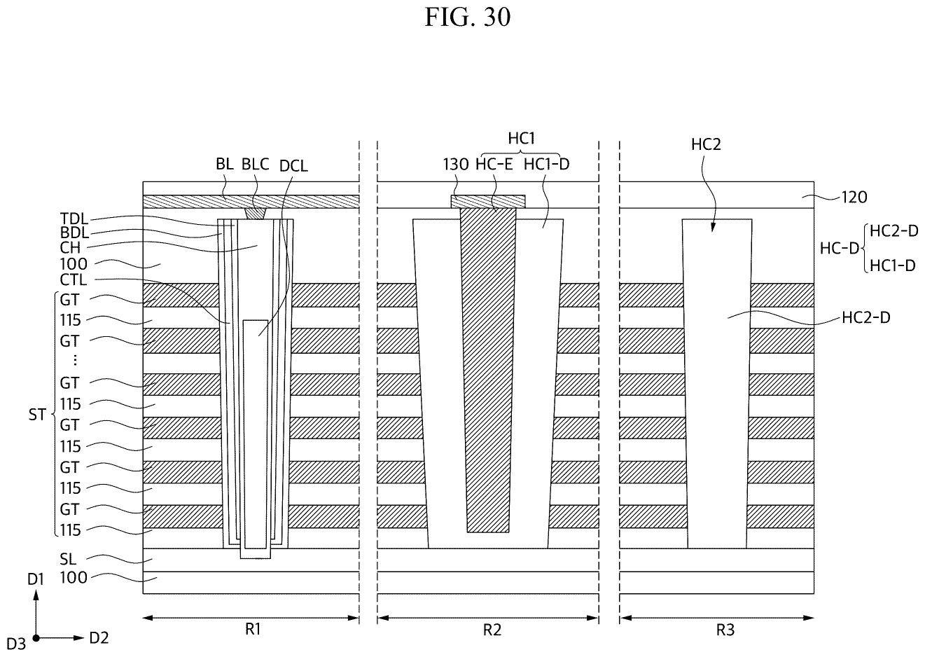

Referring to FIG. 30, the method of manufacturing the semiconductor memory device 10 may include forming the cell interconnection insulating layer 120 to surround the bit line BL and the connection structure 130.

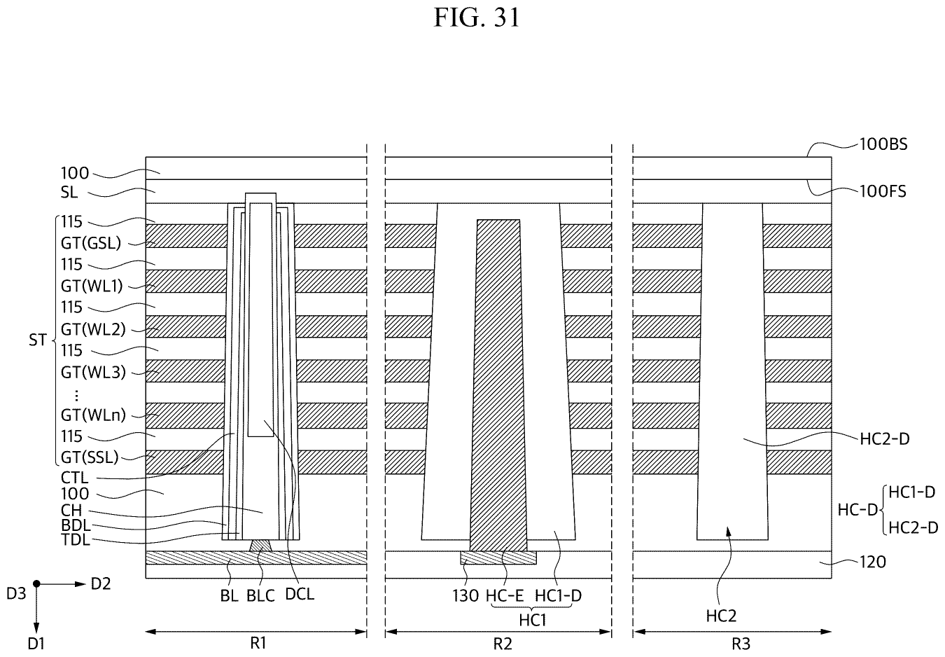

Referring to FIG. 31, the method of manufacturing the semiconductor memory device 10 may include flipping the cell substrate 100. More specifically, flipping the cell substrate 100 may indicate flipping the cell substrate 100 by 180 degrees. Based on the drawing, flipping the cell substrate 100 may indicate flipping the cell substrate 100 placed to face the bottom to face the top.

Prior to the flipping, in some example embodiments the front side of the cell substrate 100 may have a film such as photoresist and/or another protective film such as an oxide and/or silicon deposited thereupon. This film may help protect the front side of the cell substrate 100. Example embodiments are not limited thereto.

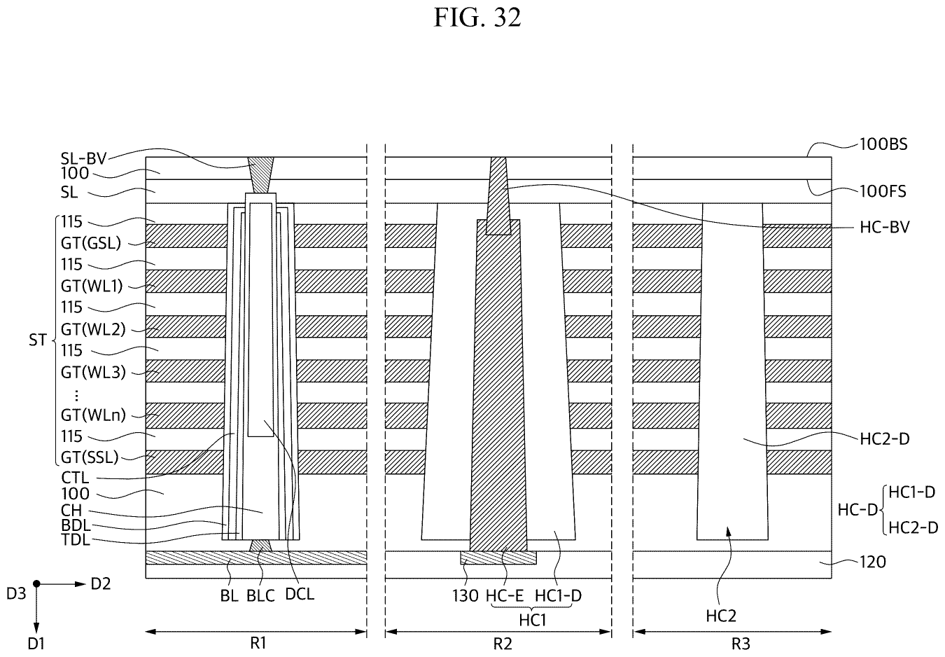

Referring to FIG. 32, the method of manufacturing the semiconductor memory device 10 may include forming the source back side contact SL-BV that penetrates the cell substrate 100 in the first direction D1 and is connected to the channel structure CHH and forming the hole cut back side contact HC-BV that penetrates the cell substrate 100 in the first direction D1 and is connected to the hole cut conductive layer HC-E.

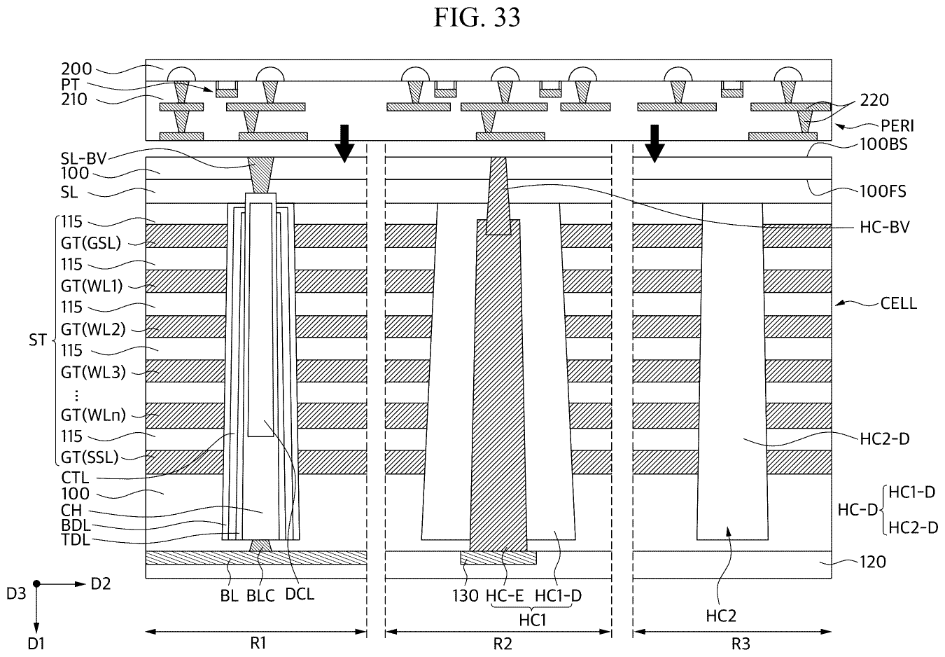

Referring to FIG. 33, the method of manufacturing the semiconductor memory device 10 may include manufacturing a cell structure CELL in the manner described above. The method of manufacturing the semiconductor memory device 10 may include connecting a cell structure CELL with a peripheral circuit structure PERI comprising the peripheral circuit interconnection structure 220 that is electrically connected with the source back side contact SL-BV and the hole cut back side contact HC-BV. In some example embodiments, the cell structure CELL may include, for example, the cell region CELL of FIG. 11, and the peripheral circuit structure PERI may include, for example, the peripheral circuit region PERI of FIG. 11.

In some example embodiments, the cell structure CELL may correspond to the memory cell array 20 of FIG. 1 described above, and the peripheral circuit structure PERI may correspond to the peripheral circuit 30 of FIG. 1 described above. The peripheral circuit structure PERI may be manufactured separately from the cell structure CELL, and in some cases may be manufactured on a separate wafer and/or substrate.

Example embodiments are described with reference to the attached drawings. However, example embodiments are not limited to the example embodiments, and some example embodiments can be manufactured in various other forms, and a person of ordinary skill in the art will understand that example can be implemented in other specific forms without changing its technical idea or essential features. Therefore, example embodiments described above should be understood in all respects as illustrative and not limiting. Furthermore, example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a cell substrate comprising a channel region and a stair region;
a plurality of hole cut structures on a front side of the cell substrate and spaced apart from each other;
a memory cell block between the plurality of hole cut structures that are spaced apart from each other; and
a connection structure comprising a conductive material,
wherein the memory cell block comprises,
a mold structure in the channel region and the stair region of the front side of the cell substrate, the mold structure comprising gate electrodes spaced apart from each other in a first direction and stacked in a stair shape in the stair region,
a channel structure penetrating at least a portion of the mold structure in the channel region in the first direction, and
a stair region via connected with the gate electrodes stacked in the stair shape in the stair region and extending in the first direction,
wherein each of the plurality of hole cut structures that are spaced apart comprises a hole cut conductive layer and a hole cut insulating layer covering at least a portion of the hole cut conductive layer and extending in a second direction intersecting the first direction, and
wherein the connection structure connects the stair region via and the hole cut conductive layer.

2. The semiconductor memory device of claim 1, wherein
a plurality of hole cut conductive layers are present, and
each of the plurality of hole cut conductive layers are spaced apart from each other.

3. The semiconductor memory device of claim 1, wherein each of the plurality of hole cut structures comprises:
a first hole cut structure comprising the hole cut conductive layer and a first hole cut insulating layer covering at least a portion of the hole cut conductive layer; and
a second hole cut structure adjacent to the first hole cut structure and including a second hole cut insulating layer.

4. The semiconductor memory device of claim 3, wherein the first hole cut insulating layer covers at least a portion of each of a side surface of the hole cut conductive layer and one surface of the hole cut conductive layer that is adjacent to the cell substrate.

5. The semiconductor memory device of claim 3, wherein a first volume of the first hole cut structure is greater than a second volume of the second hole cut structure.

6. The semiconductor memory device of claim 5, wherein a first surface area of the first hole cut structure is greater than a second surface area of the second hole cut structure, when viewed in the first direction.

7. The semiconductor memory device of claim 5, wherein a first shape of the first hole cut structure is identical to a second shape of the second hole cut structure, when viewed in the first direction.

8. The semiconductor memory device of claim 7, wherein the first shape of the first hole cut structure is identical to a third shape of the channel structure, when viewed in the first direction.

9. The semiconductor memory device of claim 5, wherein a contact point of the first hole cut structure and the second hole cut structure is present, when viewed in the first direction.

10. The semiconductor memory device of claim 1, wherein a width of the channel structure decreases as the channel structure is closer to the cell substrate in the second direction.

11. The semiconductor memory device of claim 1, wherein each of the plurality of hole cut structures penetrates at least a portion of the mold structure in the first direction, and a first width of each of the plurality of hole cut structures decreases as the each of the plurality of hole cut structures is closer to the cell substrate in the second direction.

12. The semiconductor memory device of claim 11, wherein the hole cut conductive layer extends in the first direction, and a second width of the hole cut conductive layer decreases as the hole cut conductive layer is closer to the cell substrate in the second direction.

13. The semiconductor memory device of claim 1, further comprising:
a cell insulating layer on the front side of the cell substrate and covers at least a portion of the mold structure,
wherein the cell substrate further comprises an extension region comprising an extension region contact penetrating at least a portion of the cell insulating layer in the first direction and a dummy structure including a dummy structure insulating layer.

14. The semiconductor memory device of claim 13, wherein
a plurality of dummy structures are present, and
the plurality of dummy structures are spaced apart from the extension region contact.

15. The semiconductor memory device of claim 1, wherein the stair region via does not penetrate the gate electrodes that are stacked in the stair shape.

16. A semiconductor memory device comprising:
a cell region; and
a peripheral circuit region in the cell region,
wherein the cell region comprises,
a cell substrate comprising a channel region and a stair region,
a plurality of hole cut structures on a front side of the cell substrate and spaced apart from each other,
a memory cell block between the plurality of hole cut structures that are spaced apart from each other, and
a hole cut back side contact comprising a conductive material,
wherein the peripheral circuit region comprises,
a peripheral circuit insulating layer on a back side of the cell substrate, and
a peripheral circuit interconnection structure in the peripheral circuit insulating layer,
wherein the memory cell block comprises,
a mold structure in the channel region and the stair region of the front side of the cell substrate, the mold structure comprising gate electrodes, the gate electrodes spaced apart from each other in a first direction, and stacked in a stair shape in the stair region, and
a channel structure penetrating at least a portion of the mold structure in the channel region in the first direction, and
wherein each of the plurality of hole cut structures that are spaced apart from each other comprises a hole cut conductive layer and a hole cut insulating layer covering at least a portion of the hole cut conductive layer and extending in a second direction intersecting the first direction, and
wherein the hole cut back side contact connects the peripheral circuit interconnection structure and the hole cut conductive layer.

17. The semiconductor memory device of claim 16, further comprising:
a source line contacting the channel structure; and
a source back side contact connecting the source line and the peripheral circuit interconnection structure.

18. The semiconductor memory device of claim 16, wherein each of the plurality of hole cut structures comprises:
a plurality of first hole cut structures comprising the hole cut conductive layer and a first hole cut insulating layer covering at least a portion of the hole cut conductive layer; and
at least one second hole cut structure between first hole cut structures that are adjacent to each other among the plurality of first hole cut structures and including a second hole cut insulating layer.

19. The semiconductor memory device of claim 18, wherein
a plurality of second hole cut structures are present, and
at least two or more second hole cut structures among the plurality of second hole cut structures are placed side-by-side in the second direction or at least two or more other second hole cut structures among the plurality of second hole cut structures are placed side by side in a third direction intersecting the first direction and the second direction.

20. A semiconductor memory device comprising:
a cell region; and
a peripheral circuit region in the cell region,
wherein the cell region comprises,
a cell substrate comprising a channel region and a stair region;
a plurality of hole cut structures on a front side of the cell substrate and spaced apart from each other,
a memory cell block between the plurality of hole cut structures that are spaced apart from each other,
a connection structure comprising a first conductive material, and
a hole cut back side contact comprising a second conductive material,
wherein the peripheral circuit region comprises,
a peripheral circuit insulating layer on a back side of the cell substrate, and
a peripheral circuit interconnection structure in the peripheral circuit insulating layer,
wherein the memory cell block comprises,
a mold structure in the channel region and the stair region of the front side of the cell substrate, the mold structure comprising gate electrodes spaced apart from each other in a first direction and stacked in a stair shape in the stair region,
a channel structure penetrating at least a portion of the mold structure in the channel region in the first direction, and
a stair region via connected with the gate electrodes stacked in the stair shape in the stair region and extending in the first direction,
wherein each of the plurality of hole cut structures comprises,
a first hole cut structure comprising a hole cut conductive layer and a first hole cut insulating layer covering at least a portion of the hole cut conductive layer, and
a second hole cut structure adjacent to the first hole cut structure and including a second hole cut insulating layer,
wherein the connection structure connects the stair region via and the hole cut conductive layer,
the hole cut back side contact connects the peripheral circuit interconnection structure and the hole cut conductive layer, and
a first volume of the first hole cut structure is greater than a second volume of the second hole cut structure.
